(19) United States
(12) Patent Application Publication
(10) Pub. No.: US 2025/0216706 A1
(43) Pub. Date: Jul. 3, 2025

(54) OPTICAL MODULATOR DRIVER FOR PHOTONIC INTERCONNECT PLATFORMS

(71) Applicant: Celestial AI Inc., Santa Clara, CA (US)

(72) Inventors: Matteo Staffaroni, San Ramon, CA (US); Ismail Hakki Ozguc, Santa Clara, CA (US); Kevin Park, Santa Clara, CA (US); Bengt Littman, Santa Clara, CA (US); Saurabh Vats, Palo Alto, CA (US)

(21) Appl. No.: 18/757,182

(22) Filed: Jun. 27, 2024

Related U.S. Application Data
(60) Provisional application No. 63/616,430, filed on Dec. 29, 2023.

(51) Int. Cl. G02F 1/01

(52) U.S. Cl. CPC G02F 1/0123

(57) ABSTRACT

Methods, devices, and systems for driving optical modulators. In one aspect, a driver includes a first circuit having a first switch coupled between a first input and a first output and a second circuit having a second switch coupled between a second input and a second output. Each of the first and second switches is configured to receive a control signal adjustable to control a corresponding signal path with a corresponding input electronic signal. The first and second circuits are configured to control a rising edge and a falling edge of an output electronic signal at an output of the driver that is based on a first output electronic signal at the first output and a second output electronic signal at the second output. The output of the driver is electrically coupled to the optical modulator to provide the output electronic signal to modulate an optical signal.

### CROSS-REFERENCE TO RELATED APPLICATION

This application claims priority under 35 U.S.C. § 119(e) to U.S. Provisional Patent Application Ser. No. 63/616,430, entitled “PHOTONIC INTERCONNECT PLATFORM FOR MEMORY AND COMPUTE” and filed on Dec. 29, 2023, the entire content of which is hereby incorporated by reference.

### BACKGROUND

Demands for artificial intelligence (AI) computing, such as machine learning (ML) and deep learning (DL), are increasing faster than they can be met by increases in available processing capacity. This rising demand and the growing complexity of AI models drive the need to connect many chips into a system where the chips can send data between each other with low latency and at high speed. Performance when processing a workload is limited by memory and interconnect bandwidth. In many conventional systems, data movement leads to significant power consumption, poor performance, and excessive latency. Thus, multi-node computing systems that can process and transmit data between nodes quickly and efficiently may be advantageous for the implementation of (ML) models.

### SUMMARY

A photonic interconnect platform for memory and compute is disclosed that features hybrid electro-photonic integrated circuit packages that include an electrical integrated circuit (EIC) mounted on a photonic integrated circuit (PIC). The EIC includes at least one modulator driver and at least one transimpedance amplifier (TIA). The PIC includes at least one modulator and at least one photodetector. The modulators are each in electrical communication with a corresponding modulator driver and the photodetectors are each in electrical communication with a corresponding TIA. The PIC also includes waveguides for guiding optical signals to and from the modulators and to the photodetectors. The packages encode data from electrical signals into optical signals by modulating the optical signals using the modulators. The packages encode data from optical signals into electrical signals using the photodetectors. In this way, the packages can route data to and from integrated circuits, e.g., processors or memory, which are in electrical communication with the EIC using optical signals.

In certain examples, the modulators are electro-absorption modulators (EAMs), e.g., EAMs formed in germanium silicon. Such modulators are relatively insensitive to thermal changes compared to other types of modulators for ranges of operational wavelengths, e.g., modulators using resonant structures such as ring modulators. EAMs are also relatively compact compared to other types of modulators, e.g., interference based modulators, such as Mach-Zehnder interferometers.

The relative thermal stability and compact size can allow circuit designs in which the modulators are positioned in close proximity to active electronic elements in the EIC, e.g., each modulator can be positioned in close proximity to its corresponding modulator driver. Similarly, photodetectors can be also positioned in close proximity to its corresponding TIAs in the EIC. In this context, close proximity means so close that the components in the PIC experience substantial thermal loading when the EIC is active and can experience significant changes in temperature, e.g., changes of 10° C. or more, 20° C. or more, 30° C. or more, when switching between active and inactive states.

Positioning a modulator close to its corresponding driver and/or positioning a photodetector close to its corresponding TIA allows for relatively short electrical signal lines between the passive element in the PIC and the active element in the EIC. In some cases, the lines can be so short that circuitry commonly used to reduce noise associated with longer signal lines can be omitted without unacceptable loss in fidelity of the electrical signals.

In some cases, the EIC can include other integrated circuits that generate significant thermal loads in the same chip as the drivers and TIAs. For example, the EIC can include one or more application specific integrated circuits (ASICs) in the same chip, e.g., circuits for performing processing of machine learning models/algorithms or artificial intelligence (AI) models/algorithms.

In general, the photonic interconnect platform can be used to route data between nodes on the same chip (intra-chip routing) and between nodes on different chips (inter-chip routing). Both inter-chip and intra-chip routing can include routing data over electrical channels, over photonic channels, or over both electrical channels and photonic channels.

This specification describes an optical modulator driver including an operation driver circuit and a pre-driver circuit. The optical modulator driver can improve a performance of an optical modulator using an operation driver circuit for high performance operation, using a pre-driver circuit for calibration, or a combination thereof. The techniques described in this specification can increase transmission speed and/or bandwidth, improve signal to noise ratios (SNRs) or reduce bit error rates (BERs), minimize parasitic of the driver and/or the optical modulator, and/or achieve low power consumption or dissipation.

The operation driver circuit can be active whenever code is being executed in a computing environment or a computer is otherwise performing work. The operation driver circuit is a portion of a photonic transmitter. Data packets are provided to the optical modulator driver for sending to a destination across a photonic path. The operation driver circuit modulates the optical modulator to generate a modulated optical signal that represents data, e.g., a digital packet, which is being provided to a transmitter, e.g., the driver and the optical modulator, by a digital interface from a computing unit or device, e.g., a compute node, CPU or GPU. The operation driver circuit can be configured such that data is loaded into a high speed path, and switches that control the high speed path can regulate how strong the high speed path is and there is no additional loading caused when the switches are turned off.

A switch can be controlled, e.g., changeably and digitally, by a digital-to-analog converter (DAC), to control the high speed path based on an input signal, e.g., controlling how high the input signal needs to be to pass the switch. In such a way, a rising edge and a falling edge of an output electronic signal from the optical modulator driver can be adjusted, thereby adjusting the properties of a modulated optical signal, e.g., to make the crosspoint in the middle between a higher level and a lower level. The terms “electronic signal” and “electrical signal” are used interchangeably in this specification.

The pre-driver circuit is used to calibrate the optical modulator, e.g., when the optical modulator is booted, such that the crosspoints detected by a receiver, e.g., a combination of photodiode and TIA, are within a range so that the receiver can read the signal, to minimize error bits. The pre-driver circuit can be configured to make the optical eye or the rising edge and the falling edge of the modulated optical signal, symmetric or the crosspoint in the middle by pre-distorting the output electronic signal based on known characteristics or expected characteristics of the optical modulator. The pre-driver circuit can be also digitally controlled to move the crosspoints up and down. The calibration information of the pre-driver circuit can be provided to the operation driver circuit when the operation driver circuit is active.

### BRIEF DESCRIPTION OF THE DRAWINGS

FIG. 1-1 is a diagram schematically illustrating components of an example circuit package;

FIG. 1-2 is a block diagram illustrating various components of the example circuit package of FIG. 1-1;

FIG. 1-3 is a block diagram illustrating various components of the example circuit package of FIG. 1-1;

FIG. 1-4 is a diagram illustrating a side view of an example implementation of the circuit package of FIG. 1-1;

FIG. 2-1 illustrates an example circuit package implementing an intra-chip bidirectional photonic channel between a first compute node and a second compute node;

FIG. 2-2 illustrates an example circuit package implementing an inter-chip bidirectional photonic channel between a compute node and an additional compute node located on an additional circuit package;

FIG. 3-1 is a diagram illustrating an example circuit package implementing multiple compute nodes and electronic channels;

FIG. 3-2 is a diagram illustrating an example circuit package implementing multiple compute nodes and bidirectional photonic channels;

FIG. 3-3 is a diagram illustrating the circuit package of FIG. 3-2 implementing both electronic channels and bidirectional photonic channels;

FIG. 3-4 is a diagram illustrating a circuit package implementing multiple compute nodes and inter-chip directional photonic channels;

FIG. 3-5 is a diagram illustrating an example circuit package implementing all the features of FIG. 3-1 through FIG. 3-4;

FIG. 4 is a diagram illustrating an example implementation of four of the circuit packages of FIG. 3-4 or 3-5 being interconnected;

FIG. 5 is a diagram illustrating an example driver for an optical modulator;

FIG. 6-1 is a circuit diagram illustrating an example driver for an optical modulator;

FIG. 6-2 is a diagram illustrating an example of operating the operation driver circuit of FIG. 6-1 to control optical eye diagrams;

FIG. 7-1 is a diagram illustrating another example driver for an optical modulator;

FIG. 7-2 is a circuit diagram illustrating an example inverting circuit; and

FIG. 7-3 is a diagram illustrating an example of operating the driver of FIG. 7-1 to control optical eye diagrams.

Like reference numbers and designations in the various drawings indicate like elements.

### DETAILED DESCRIPTION

This specification describes computing systems, implemented by one or more circuit packages, which achieve reduced power consumption and/or increased processing speed as a result of the data-movement-related technologies described in this specification. In particular, power consumed for data movement is reduced by increasing data locality in each circuit package and reducing energy losses when data movement is needed compared to conventional computer systems. Power-efficient data movement, in turn, can be accomplished by moving data over small distances in the electronic domain, while leveraging photonic channels for data movement in scenarios where the resistance in the electronic domain and/or the speed at which the data can move in the electronic domain leads to bandwidth limitations. Thus, in some examples, each circuit package includes an electronic integrated circuit (EIC) that includes multiple compute nodes that are connected by bidirectional photonic channels, e.g., implemented in a PIC in a separate layer or chip of the package, into a hybrid, electronic-photonic (also referred to as an electro-photonic) network-on-chip (NoC). Multiple such NoCs may be connected, by inter-chip bidirectional photonic channels, e.g., channels implemented over optical fiber, between respective circuit packages, into a larger electro-photonic network, to scale the computing system to arbitrary size without incurring significant power or speed losses.

While the described computing systems and their various novel aspects are generally applicable to a wide range of processing tasks, they are particularly suited to implementing ML models, in particular, artificial neural networks (ANNs). As applied to ANNs, a circuit package and system of interconnected circuit packages as described in this specification are also referred to as an “ML processor” and “ML accelerator,” respectively.

Neural networks are machine learning models that include one or more layers of artificial neurons that compute neuron output activations from weighted sums of a set of input activations. These computations correspond to Multiply-Accumulate (MAC) operations. For a given neural network, the flow of activations between nodes and layers is fixed. Further, once training of the neural network is complete, the neuron weights in the weighted summation, and any other parameters associated with computing the activations, are likewise fixed. Thus, a NoC lends itself to implementing a neural network by assigning neural nodes to compute nodes, pre-loading the fixed weights associated with the neural nodes into memory of the respective compute nodes and configuring data routing between the compute nodes based on the predetermined flow of data between the neural nodes. The weighted summation can be efficiently performed using a dot product engine, also called a “digital neural network (DNN)” due to its applicability to ANNs.

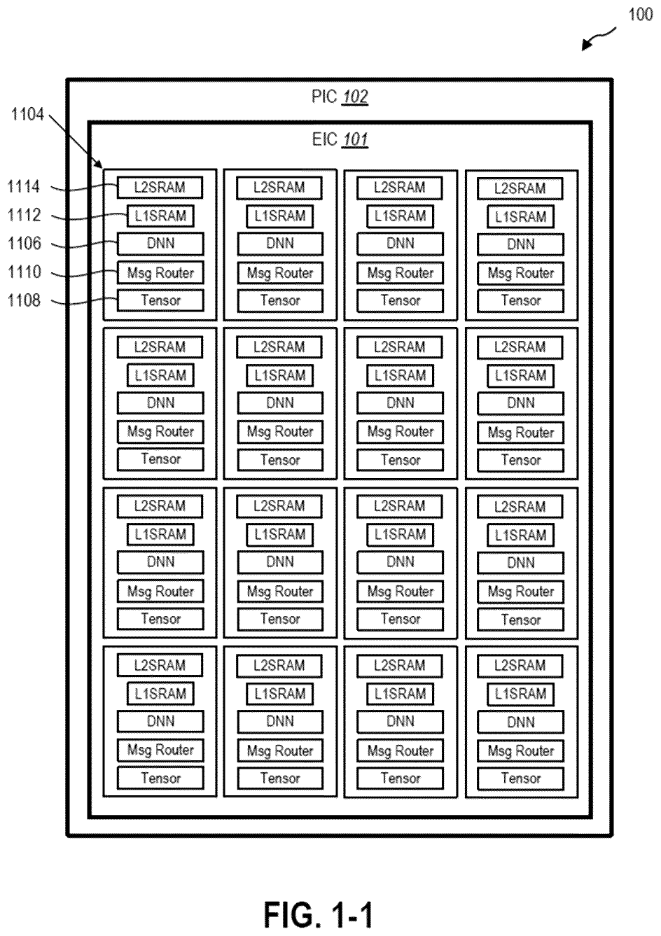

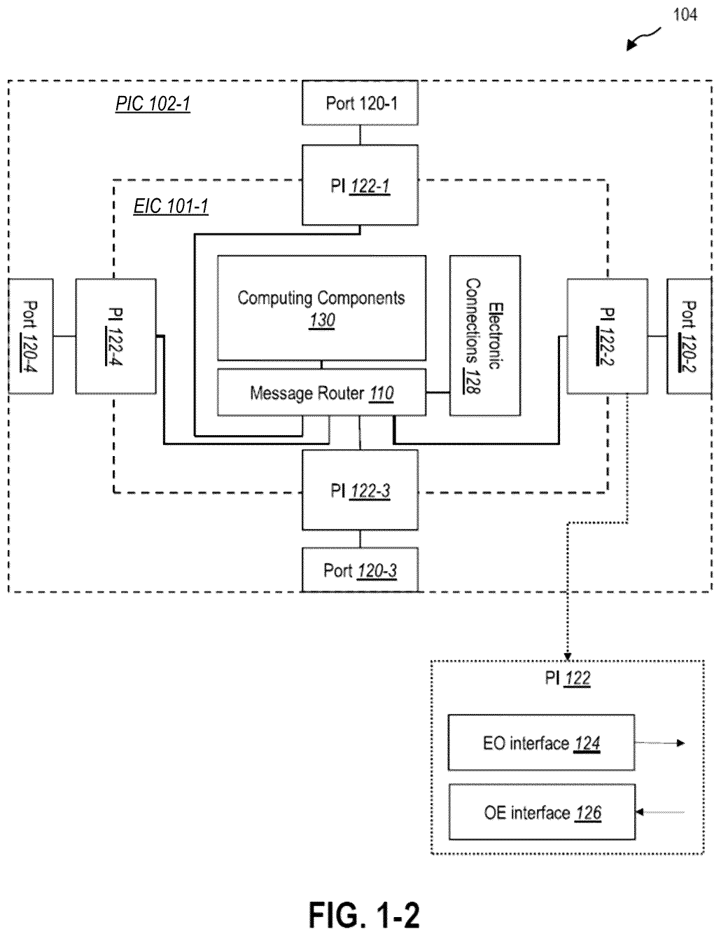

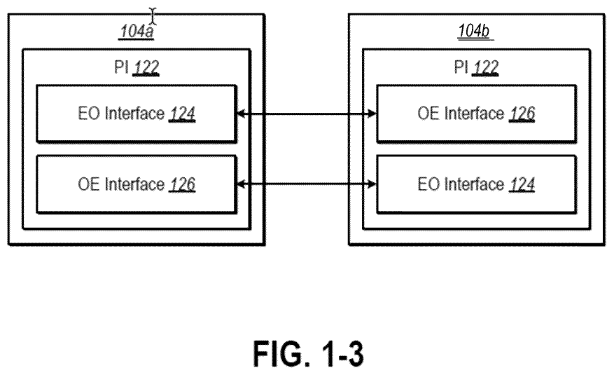

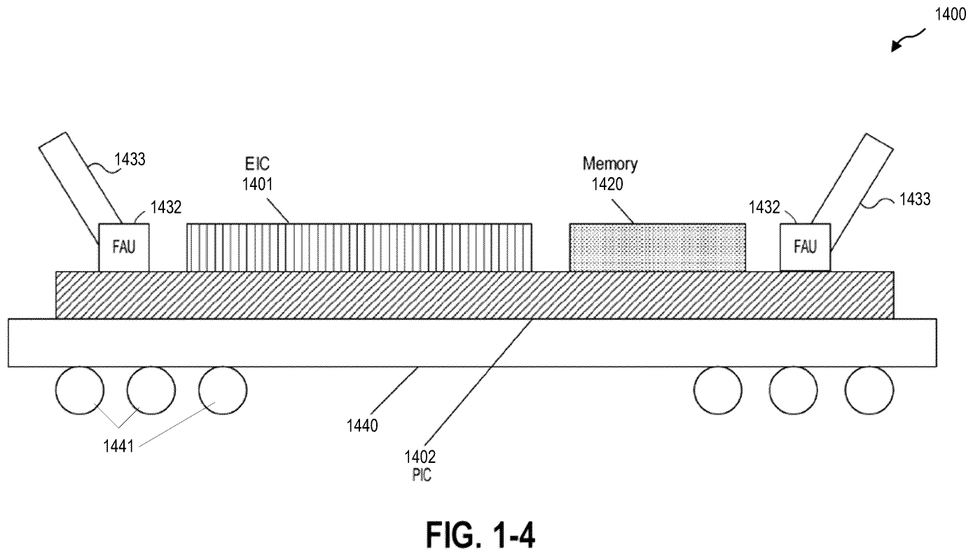

FIG. 1 is a diagram schematically illustrating components of an example circuit package 100. The circuit package 100 may serve, for example, as an ML processor. The circuit package 100 includes an electronic integrated circuit 101 (EIC), such as, for example, a digital and mixed-signal application-specific integrated circuit (ASIC), and a photonic integrated circuit 102 (PIC). The EIC 101 and PIC 102 are formed in different layers of the circuit package 100, which will be called the “electronic circuit layer” and “photonic circuit layer,” respectively, one stacked above the other, for example, using copper pillars, bump attachments, or other means to create an electrical interconnect to transmit and receive messages, packets, and/or other data between the EIC and the PIC, as illustrated further below with reference to FIG. 1-4. The PIC or PICs 102 receive light from one or more laser light sources that may be integrated into the PIC 102 itself or implemented separately from the PIC 102 either within or externally to the circuit package 100 and coupled into to the PIC 102 by suitable optical couplers. The optical couplers and laser sources are omitted from FIG. 1-1, but shown, for example, in FIG. 1-4. Generally, the laser sources and optical couplers are selected to provide optical signals within a band of wavelengths for which the PIC 102 and other optical components in the system is intended to operate. In some examples, the operational wavelengths are in a range from 1,500 nm to 1,600 nm, e.g., in the band of the spectrum referred to as the C-band and/or L-band.

The EIC 101 includes multiple compute nodes 1104. As will be described in detail, the compute nodes 1104 may communicate with each other over one or more intra-chip bidirectional channels. The intra-chip bidirectional channels may include one or more bidirectional photonic channels, e.g., implemented with optical waveguides in the PIC 102, and/or one or more electronic channels, e.g., implemented in the circuitry of the EIC 101. The compute nodes 1104 may but need not in all examples be electronic circuits identical or at least substantially similar in design, and as shown, may form “tiles” of the same size arranged in a grid or any other arrangement suitable for performing the computations described herein.

In the present example, the EIC 101 has sixteen compute nodes 1104 arranged in a four-by-four array, but the number and arrangement of compute nodes can generally vary. More generally, neither the shape of the compute nodes nor the grid in which they are arranged need necessarily be rectangular; for example, oblique quadrilateral, triangular, or hexagonal shapes and grids, as well as topologies with 3 or more dimensions, can also be used. Further, although tiling may provide for efficient use of the available on-chip real-estate, the compute nodes 1104 need not be equally sized and regularly arranged in all implementations. As shown in FIG. 1-1, in some examples, the compute nodes 1104 are arranged in a rectilinear array, e.g., a conceptually square array.

Each compute node 1104 in the EIC 101 may include one or more circuit blocks serving as processing engines. For example, in the implementation shown in FIG. 1-1, each compute node 1104 includes a dot product engine, or DNN, 1106 and a tensor engine 1108. The DNN 1106 performs MAC operations rapidly and at reduced energy per operation to execute either a convolution function or a dot product function, e.g., as routinely used in neural networks. The tensor engine 1108 can perform other, non-MAC operations, e.g., implementing non-linear activation functions as applied to the weighted sums in a neural network. In other examples, the compute node 1104 can have any combination of processing elements such as CPUs, GPUs, TPUs, and the like, and the DNN 1106 and tensor engine 1108 can also be included or omitted depending on the application.

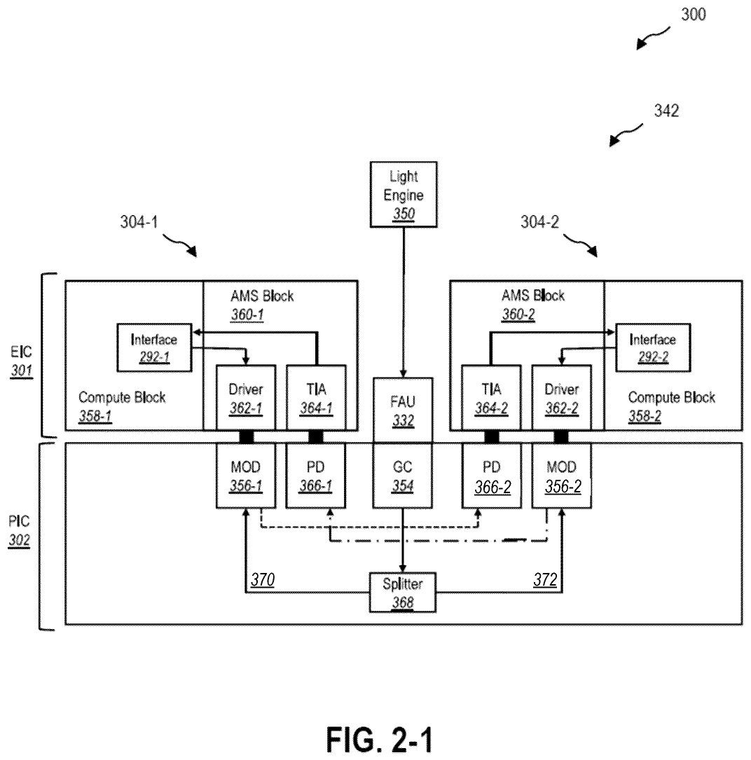

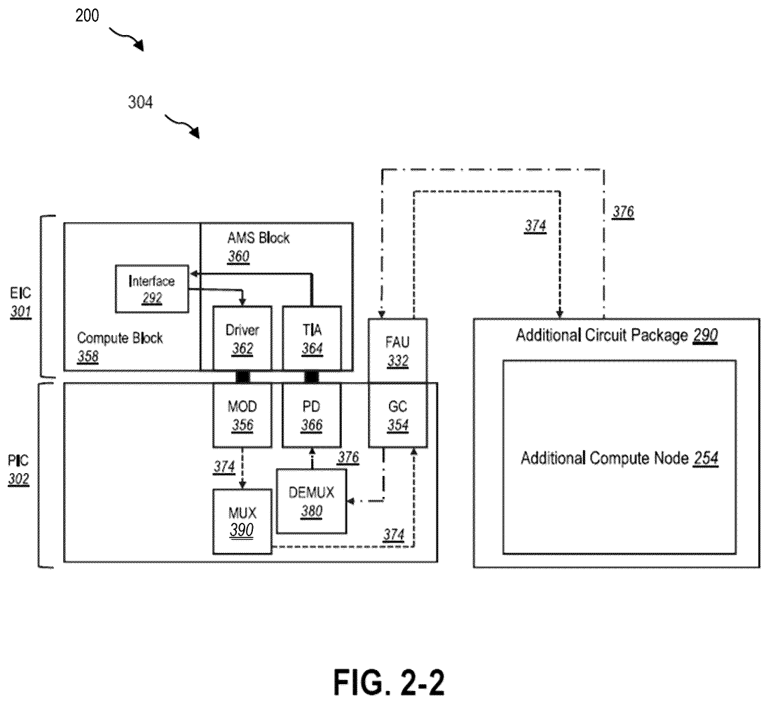

Each compute node 1104 includes a message router 1110. The message routers 1110 interface with channels, e.g., electronic and/or photonic channels as described below in reference to FIG. 1-2, to facilitate data flow to and from the compute nodes 1104. Further, the compute nodes 1104 each have a memory system, e.g., including level-one static random-access memory (L1SRAM) 1112 and level-two static random access memory (L2SRAM) 1114. L1SRAM 1112 is optional and, if included, can serve as scratchpad memory for each compute node 1104. L2SRAM 1114 may function as the primary memory for each compute nodes 1104 and may store certain fixed operands used by the DNN 1106 and tensor engine 1108, e.g., the weights of a machine learning model, in close physical proximity to the DNN 1106 and tensor engine 1108. L2SRAM 1114 may also store any intermediate results used in executing the machine learning model or other computation.

FIG. 1-2 is a block diagram illustrating various components of an example of the compute node 1104 of FIG. 1-1. Here, a compute node 104 includes various computing components 130, which may include the DNN 1106, the tensor engine 1108, interface controllers, routing controllers, the L1SRAM 1112 and/or the L2SRAM 1114, among other components. In some examples, the computing components 130 include memory components, e.g., a memory controller, vertically stacked high-bandwidth memory, etc., such that the compute node 104 may be a memory node as will be described. The computing components 130 are implemented on an EIC 101-1 of the compute node 1104 and are in communication with the message router 110. For example, the message router 110 may receive messages from another computing component over one of optical ports or electronic connections 128, and additionally may send messages generated by the respective compute node 104 of the message router 110 over one of the optical ports or the electrical connects 128. The message router is implemented on the EIC 101-1 and may be implemented through hardware, software, or a combination of hardware and software. The message router is shown as a single block but can also include a message router associated with each photonic interface. The PIC 102 and EIC 101 as shown in FIG. 1-2 may be a portion of the PIC 102 and/or EIC 101 of FIG. 1-1 and may include various other computing componentry.

In some examples, the compute node 104 connects to one or more computing components through electronic channels, e.g., intra-chip electronic channels. For example, as will be described below in detail, the various compute nodes 104 in FIG. 1-1 may each connect to adjacent nodes via the electronic channels. The compute node 104 may connect to any other computing component through one or more electronic channels. In some examples, the compute node 104 is configured to connect to up to 4 adjacent compute nodes 1104 through electronic channels. In some examples, the compute nodes 104 are connected to additional componentry and/or nodes through electronic connections and can process data in the electrical domain within the compute node 104, using an electrical port which is included in the electronic connections 128. The electronic channels connected to the compute node 104 may each connect to the message router 110, represented by electronic connections 128. The electronic connections 128 may be implemented in the EIC 101 of the compute node 104. Messages or packets sent through the electronic connections 128 may therefore pass to and be acted on by the message router 110 to forward those messages on to additional computing components, or to pass the messages internally to the computing components 130 of the compute node 104. In this way, the compute node 104 and more specifically the message router 110 may be connected to and communication with one or more computing components through the electronic connections 128.

In some examples, the compute node 104 is connected to one or more photonic channels. For example, as shown in FIG. 1-2, the compute node 104 includes four photonic ports 120-1, 120-2, 120-3, and 120-4, collectively, photonic ports 120. The four photonic ports 120-1 to 120-4 connect to four photonic channels. The photonic ports 120 facilitate connecting a photonic connection to the compute nodes 104. For example, the photonic ports 120 may include and/or may connect to one or more waveguides to direct an optical signal to and/or from the compute node 104. The photonic ports 120 are implemented in the PIC 102-1. In some examples, the photonic channels are bidirectional photonic channels to facilitate both sending and receiving communications through the photonic ports 120. For example, each bidirectional photonic channel may include two or more unidirectional links, e.g., one or more sending links and one or more receiving links. The unidirectional links may be associated with and may connect to respective sending and receiving components of the photonic interfaces 122, as described below. In this way, the photonic ports 120 facilitate connecting the compute node 104 to one or more bidirectional photonic channels to communicate photonically with other computing devices.

Each of the photonic ports 120 is associated with and connected to a corresponding photonic interface 122 (PI), e.g.,—photonic port 120-1 is connected to photonic interface 122-1, etc. The photonic interfaces 122 facilitate converting a signal between the electronic domain and the photonic domain. In particular, each photonic interface, e.g., as illustrated for photonic interface 122-2, includes an electrical-to-optical (EO) interface 124 for converting electronic signals to optical signals, and include an optical-to-electrical (OE) interface 126 for converting optical signals to electronic signals. While FIG. 1-2 only shows PI 122-2 as having the EO interface 124 and OE interface 126, it should be understood that each of the PIs 122 may include one or both of these interfaces and typically includes multiple ones of each to support multiple unidirectional photonic links in both directions connecting to the port, for example, to support wavelength division multiplexing (WDM) or other schemes.

As described above, each bidirectional photonic channel may include two or more unidirectional photonic links. Each unidirectional photonic link may include or may be associated with both an EO interface 124 and an OE interface 126. For example, as shown in FIG. 1-3, an EO interface 124 of a compute node 104a connects, e.g., via photonic ports 120 and waveguides, etc., to an OE interface 126 of another computing device 104b, e.g., another instance of the compute node, to form a unidirectional photonic link for sending packets from the compute node 104a to the other computing device 104b. Similarly, an EO interface 124 of the other computing device 104b connects to an OE interface 126 of the compute node 104a to form a unidirectional link for receiving packets to the compute node 104a from the other computing device 104b. In this way, the PIs 122 may facilitate bidirectional communication over the bidirectional photonic channels connected to the photonic ports 120.

In some cases, the PIs 122 each include various optical and electronic components. For example, the EO interface 124 can include an optical modulator and an optical modulator driver. The optical modulator generally operates on an optical, e.g., laser, carrier signal to encode information into the optical carrier signal and thereby transmit information optically. The optical modulator may be controlled or driven by the optical modulator driver. The optical modulator driver may receive an electronic signal, e.g., packet encoded into an electronic signal, from the message router 110 and may control a modulation of the modulator to convert or encode the electronic signal into the optical signal. In this way the optical modulator and driver may make up the EO interface 124 that optically transmits data from the compute node 104.

The modulator can be an electro-absorption modulator (EAM), which is a semiconductor device that modulates the intensity of an optical signal by varying absorption of the optical signal as it traverses the modulator based on an electric voltage applied to the EAM. Generally, the principle of operation of an EAM is based on the Franz-Keldysh effect, i.e., a change in the absorption spectrum caused by an applied electric field, which changes the bandgap energy, and thus the photon energy of an absorption edge, but usually does not involve the excitation of carriers by the electric field.

EAMs can be made in the form of a waveguide with electrodes for applying an electric field in a direction perpendicular to the modulated optical signal. In certain examples, the EAM is implemented in a layer of germanium silicon, e.g., an epitaxially-grown layer of GeSi. Germanium can stoichiometrically constitute 90% or more of the GeSi material, e.g., 95% or more, 96% or more, 97% or more, 98% or more, or 99% or more.

In some examples, the OE interface 126 includes a photodiode and a transimpedance amplifier (TIA). The photodiode receives an optical signal, e.g., from another computing device, through a unidirectional link of the bidirectional photonic channel and converts the optical signal into an electronic signal. The photodiode may be connected to the TIA which may include circuitry for gain control and normalizing the signal level to extract and communicate a bit stream to the message router 110. In this way, the OE interface 126 may include the photodiode and the TIA to optically receive data in the compute node 104.

In some cases, the PIs 122 are partially implemented in the PIC 102-1 and partially implemented in the EIC 101-1. For example, the optical modulator may be implemented in the PIC 102-1 and may be electrically coupled to the optical modulator driver implemented in the EIC 101-1. For example, the EIC 101-1 and the PIC 102-1 may be vertically stacked and the optical modulator and the optical modulator driver may be coupled through an electronic interconnect of the two components, e.g., a copper pillar and/or bump attachment of various sizes. Similarly, the photodiode may be implemented in the PIC 102-1 and the TIA may be implemented in the EIC 101-1. The photodiode and the TIA may be coupled through an electronic interconnect of the two components.

As shown in FIG. 1-2, each PI 122 is in communication with the message router 110. The PIs 122 are connected to the message router 110 through electronic interconnects in the EIC 101-1. The PIs 122 communicate with the message router 110 to transmit signals to and/or receive signals to or from the message router 110. In some examples, the message router 110 includes electronic circuitry and/or logic to convert a data packet into an electronic signal and then an optical signal in conjunction with the EO interface 124. Similarly, the message router 110 may include electronic circuitry and/or logic to convert an optical signal into an electronic signal and then into a data packet through the OE interface 124. In this way, the message router 110 may convert and/or operate on data between the electronic domain and the optical domain.

The message router 110 may route information and/or data packets to and/or from the compute node 104. For example, the message router 110 may examine an address contained in a message and determine that the message is destined for the compute node 104. The message router 110 may accordingly forward or transmit some or all of the message internally to the various computing components 130 of the compute node 104, e.g., over an electronic connection. In another example, the message router 110 may determine that a message is destined for another computing device, e.g., the message either being generated by the compute node 104 or received from one computing device for transmission to another computing device. The message router 110 may accordingly forward or transmit some or all of the message through one or more of the channels, e.g., electronic or photonic, of the compute node 104 to another computing device. In this way, the message router 110 in connection with the electronic connections 128 and the bidirectional photonic channels connected to the photonic ports 120 may be part of an implementation of the compute node 104 in a network of computing devices for generating, transmitting, receiving, and forwarding messages between various computing devices. In some cases, the compute node 104 is implemented in a network of multiple compute nodes 104 such as that shown in FIG. 1-1.

The PIC 102-1 includes one or more waveguides. A waveguide is a structure that guides and/or confines light waves to propagate the light along a desired path and to a desired location. For example, a waveguide may be an optical fiber, a planar waveguide, a glass-etched waveguide, a photonic crystal waveguide, a free-space waveguide, any other suitable structure for directing optical signals, and combinations thereof. In some examples, one or more internal waveguides are formed in the PIC 102-1. In certain examples, one or more external waveguides are implemented external to the PIC 102-1, e.g., an optical fiber or a ribbon comprising multiple optical fibers.

The PIC 102-1 may include one or more waveguides in connection with the photonic ports 120. For example, as will be described below in more detail, one or more of the photonic ports 120 may be connected to another port of another compute node included in the circuit package 100, e.g., on a same chip as the compute node 104. Such connections may be intra-chip connections. In some examples, an internal waveguide is implemented, e.g., formed, in the PIC 102-1 to connect these photonic ports internally to the chip. In another example, one or more photonic ports 120 may be connected to a photonic port of another computing device located in a separate circuit package or separate chip to form inter-chip connections. In some examples, an external waveguide is used to connect these photonic ports across the multiple chips. For example, the photonic ports 120 may be connected by optical fiber across the multiple chips. In some examples, an external waveguide, e.g., optical fiber, connect directly to the photonic ports 120 of the respective computing devices across the multiple chips. In some examples, an external waveguide is connected to one or more internal waveguides formed in the PICs 102 of one or more of the chips. For example, one or more internal waveguides may internally connect the one or more of the photonic ports 120 to one or more additional optical components located at another portion of the circuit package, e.g., another portion of the PIC 102, to facilitate coupling of optical signals to and/or from the external waveguides. For example, the internal waveguides may connect to one or more optical coupling structures including fiber array units (FAUs) located over grating couplers, or edge couplers. In some examples, one or more FAUs are implemented to facilitate coupling the external waveguides to the internal waveguides to facilitate chip-to-chip interconnection to another circuit package to both transmit and receive. For example, one or more FAUs can be used to supply optical power from an external laser light source to the PIC 102-1 to drive the photonics, e.g., provide one or more carrier signals, in the PIC 102-1.

FIG. 1-4 is a diagram illustrating a side view of an example structural implementation 1400 of the circuit package 100 of FIG. 1-1. In this example, an EIC 1401 and a PIC 1402 are formed in separate semiconductor chips, typically silicon chips, although other semiconductor materials may be used. PIC 1402 is disposed directly on a substrate 1440, shown with solder bumps, for subsequent mounting to a printed circuit board (PCB). The EIC 1401 and FAUs 1432 that connect the PIC 1402 to external waveguides 1433, e.g., optical fibers, are disposed on top of and optically connected to the PIC 1402. Optionally, and as will be described below, the circuit package 1400 may further include, as shown, an on-chip memory 1442 positioned on top of the PIC 1402 adjacent to the EIC 1401.

As will be appreciated, the depicted structure of the circuit package 1400 is merely one of several possible ways to assemble and package the various components. In some examples, some or all of the EIC 1401 is disposed on the substrate. In some examples, some or all of the PIC 1402 is placed on top of the EIC 1401. In some examples, it is also possible to create the EIC 1401 and PIC 1402 in different layers of a single semiconductor chip. In some examples, the photonic circuit layer includes or is made of multiple PICs 1402 in multiple sub-layers. Multiple layers of PICs 1402, or a multi-layer PIC 1402, may help to reduce waveguide crossings. Moreover, the structure depicted in FIG. 1-4 may be modified to included multiple EICs 1401 connected to a single PIC 1402. For example, the multiple EICs 1401 may be connected to each other by photonic channels in the PIC 1402.

In general, the EICs and PICs can be manufactured using standard wafer fabrication processes. Further, in some examples, heterogeneous material platforms and integration processes are used. For example, various active photonic components, e.g., the laser light sources and/or optical modulators and photodetectors used in the photonic channels, may be implemented using group III-V semiconductor components.

The laser light source(s) can be implemented either in the circuit package 1400 or externally. When implemented externally, a connection to the circuit package 1400 may be made optically using a grating coupler in the PIC 1402 underneath an FAU 1432 as shown and/or using an edge coupler. In some cases, lasers are implemented in the circuit package 1400 by using an interposer containing several lasers that can be co-packaged and edge-coupled with the PIC 1402. In some cases, the lasers are integrated directly into the PIC 1402 using heterogenous or homogenous integration. Homogenous integration allows lasers to be directly implemented in the silicon substrate in which the waveguides of the PIC 1402 are formed, and allows for lasers of different materials, such as indium phosphide (InP), and architectures such as quantum dot lasers. Heterogenous assembly of lasers on the PIC 1402 allows for group III-V semiconductors or other materials to be precision-attached onto the PIC 1402 and optically coupled to a waveguide implemented on the PIC 1402.

As will be described in further detail below, several circuit packages 1400 may be interconnected to result in a single system providing a large electro-photonic network, e.g., by connecting several chip-level electro-photonic networks as described below. Multiple circuit packages configured as ML processors may be interconnected to form a larger ML accelerator. For example, the photonic channels within the several circuit packages or ML processors, the optical connections, the laser light sources, the passive optical components, and the external optical fibers on the PCB, may be utilized in various combinations and configurations along with other photonic elements to form the photonic fabric of a multi-package system or multi-ML-processor accelerator.

FIG. 2-1 illustrates an example of a circuit package 300 implementing an intra-chip bidirectional photonic channel 342 between a first compute node 304-1 and a second compute node 304-2. The circuit package 300 includes various electronic and optical components implemented across an EIC 301 and a PIC 302. Package 300 includes two compute nodes 304-1 and 304-2, collectively, compute nodes 204, which each include a respective compute block 358-1 and 358-2 which may include various processing, storage, and/or communication functions. The compute nodes 304 each include an Analog Mixed Signal (AMS) block 360-1 and 360-2, collectively AMS blocks 360, that includes analog/mixed signal circuits for interfacing with the PIC 302. The compute blocks 358 each include an interface 292-1 and 292-2, collectively interfaces 292, for communicating with the AMS blocks 360, or more specifically, with the componentry of the AMS blocks 360. The AMS blocks 360 each include a modulator driver 362-1 and 362-2, collectively drivers 362, and each include a transimpedance amplifier 364-1 and 364-2, collectively TIAs 264.

The PIC 302 includes a pair of modulators 356-1 and 356-2 and a pair of photodetectors 366-1 and 366-2. The PIC 302 also includes a grating coupler 354 or other optical interface (OI) configured to receive and pass on light to one or more components and a splitter 368.

A light engine 350 provides an optical carrier signal for communication between the first compute node 304-1 and second compute node 304-2. The light engine 350 provides the carrier signal to a FAU 332 of the circuit package 300, such as through an optical fiber. The FAU 332 is optically coupled to the grating coupler 354 which directs the optical carrier signal on to other components of the electronics package 300. A splitter 368 receives the optical carrier signal from the grating coupler 354 and splits the optical signal along two optical paths 370 and 372. More generally, the splitter 368 may distribute the optical carrier signal over any number of photonic paths. The optical paths 270 and 272 may be implemented as any suitable optical transmission medium and may include a mixture of waveguides and optical fibers, or any other suitable transmission medium. In the present example, the optical paths 270 and 272 are implemented as waveguides in the PIC 302.

The optical paths 370 and 372 pass from the splitter 368 to the optical modulators 356-1 and 356-2, respectively. Each optical modulator modulates the optical carrier signal it receives from the splitter 368 based on information from its respective optical driver 362-1 and 362-2 and transmits the modulated signal along the respective optical path. A first photodetector 266-1 receives the modulated signal from the optical path, e.g., from the associated modulator 256. As depicted, the optical path from modulator 356-1 connects to photodetector 266-2 and the optical path from modulator 356-2 connects to photodetector 266-1. The photodetectors convert the received modulated signal into respective electrical signal and pass the electrical signals to a transimpedance amplifier 264 through which the compute nodes 304-1 and 304-2 receive the information encoded in the signals. In this way, communication occurs between the compute nodes through the various components just described. The PIC 302 described here includes an intra-chip bidirectional photonic channel, including two unidirectional photonic links for communicating both to and from each compute node. Here, the first unidirectional photonic link is defined by the modulator driver 362-1, the optical modulator 356-1, the optical path 370, the photodiode 366-2, and the transimpedance amplifier 364-2. Similarly, the second unidirectional link is defined by the modulator driver 362-2, the optical modulator 356-2, the optical path 370, the photodiode 366-1, and the transimpedance amplifier 364-1. The first and second unidirectional links operate in opposite directions. Additionally, one or more of the compute nodes 304 may include one or more serializers and/or deserializers for communicating signals between the compute nodes 304. In this way, the two unidirectional photonic links form the intra-chip bidirectional photonic channel 342.

FIG. 2-2 illustrates an example circuit package 200 implementing an inter-chip bidirectional photonic channel between the compute node 304 and an additional compute node 254 located on an additional circuit package 290, such as a memory node on a memory circuit package. The compute node 304 and/or the electronics package 200 may include the EIC 301 and the PIC 302 including the components described above with reference to FIG. 2-1. Further, PIC 302 includes a demultiplexer 380 and a multiplexer 390. In general, a demultiplexer and multiplexer can be used in a PIC for wavelength division multiplexing of optical signals.

In the inter-chip configuration shown in FIG. 2-2, the optical modulator 356 transmits a modulated signal along an optical path 374 to the grating coupler 354. The modulated signal is passed through the multiplexor 390 prior to passing to the grating coupler 354. From the grating coupler 354, the modulated signal travels through the FAU 332 and along an optical fiber to another grating coupler of the additional circuit package 290, where the receiving componentry of the additional circuit package 290 receives and processes the incoming signal. The receiving componentry may be the same as or similar to the receiving componentry of the circuit package 300 described above or may include any other means for receiving and processing the incoming signal.

Similarly, the additional circuit package 290 can generate and transmit a signal to the compute node 304. The additional circuit package 290 may generate and transmit the signal using transmitting componentry that may include transmitting componentry similar to or the same as that of the circuit package 300 described above, or any other means. The additional circuit package 290 transmits a signal, for example, along an optical fiber to the FAU 332 and grating coupler 354 of the compute node 304. The signal travels along an optical path 276 to the photodetector 366 which converts the optical signal to an electrical signal as described herein. The received signal passes through the demultiplexer 280 prior to passing to the photodetector 266. In this way, an inter-chip bidirectional photonic channel is defined by two unidirectional photonic links. Here, the first unidirectional photonic link is defined by the modulator driver 362, the optical modulator 356, the optical path 374, the multiplexor 378, the grating coupler 354, the FAU 332, an optical fiber, and receiving componentry of the additional circuit package. Similarly, the second unidirectional photonic link is defined by the transmitting components of the additional circuit package 290, the optical fiber, the FAU 332, the grating coupler 354, the demultiplexer 380, the optical path 376, the photodetector 366, and the transimpedance amplifier 364. The first and second unidirectional photonic links operate in opposite directions. In this way the two unidirectional photonic links forms the inter-chip bidirectional photonic channel.

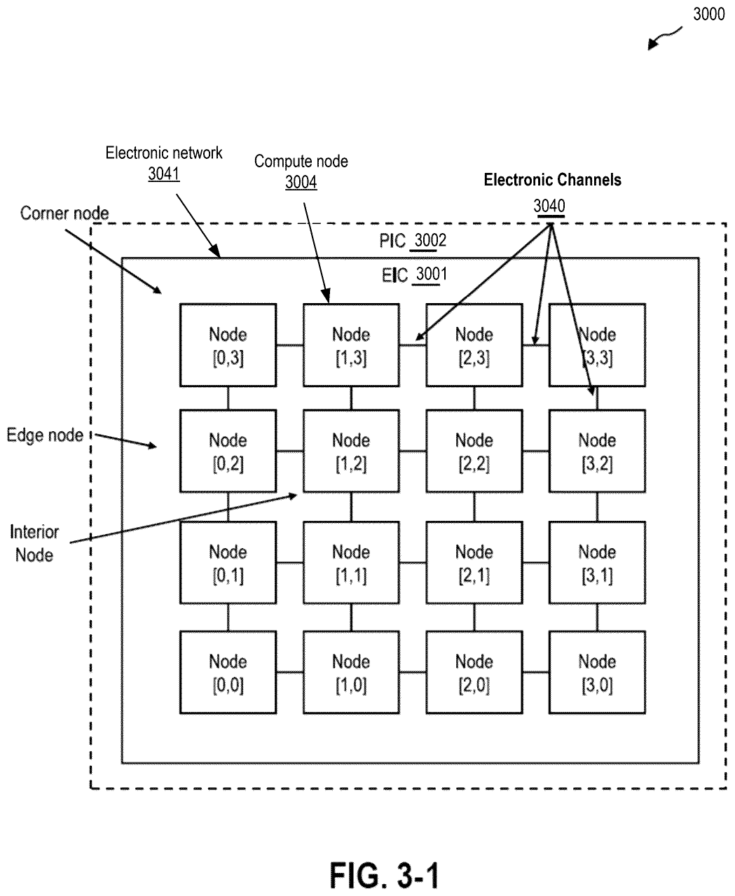

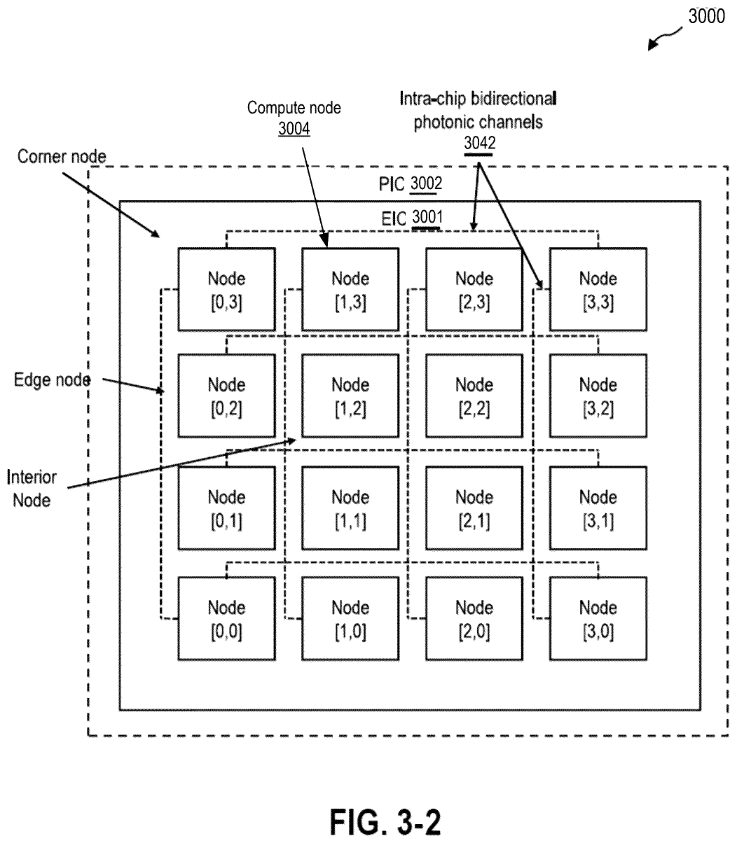

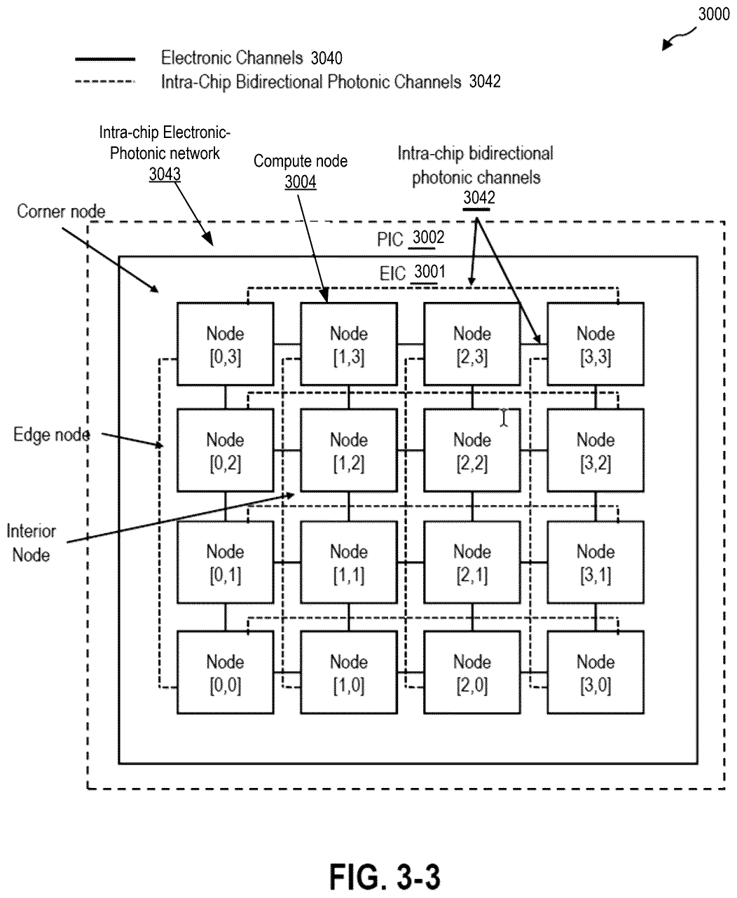

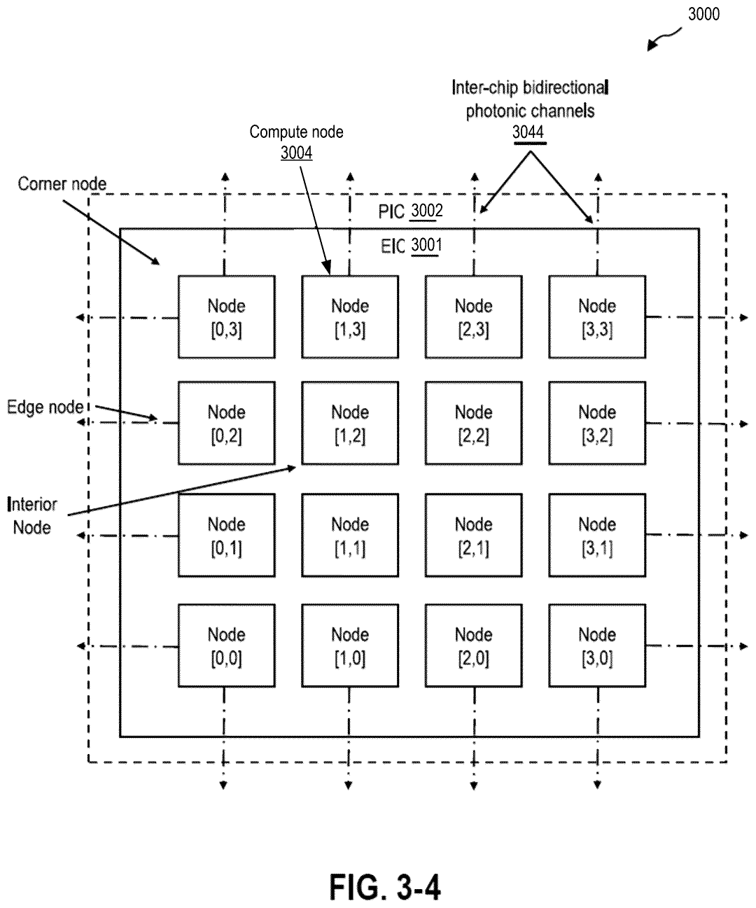

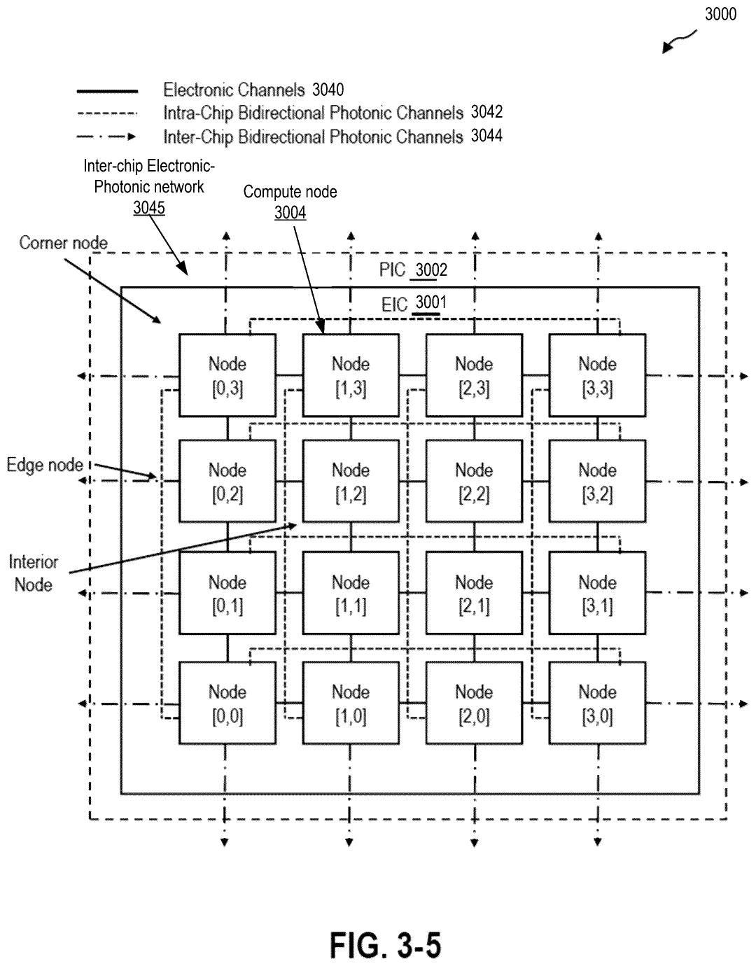

FIG. 3-1 is a diagram illustrating an example of a circuit package 3000 implementing multiple compute nodes 3004. Each compute node 3004, and more specifically, a message router in each compute node 3004, connects to one or more electronic channels 3040. The compute nodes 3004, e.g., via the message routers, direct messages transmitted over the electronic channels 3040, e.g., those described with reference to FIG. 1-2. Additionally, the circuit package includes an EIC 3001 and a PIC 3002, with the compute nodes 3004, routers, and electronic channels 3040 being implemented on the EIC 3001 as described herein. The circuit package may include additional circuitry and/or componentry in addition to that shown in FIG. 3-1.

The sixteen compute nodes 3004 are arranged in a four by four array are indexed, for case of reference, according to the cartesian coordinates [0,0] through [3,3] as shown. The array of the compute nodes 3004 includes four corner nodes, eight non-corner edge nodes, hereinafter “edge nodes”, and four interior nodes. More generally, circuit packages may include any number of compute nodes, and the compute nodes may be arranged in any array, configuration, or arrangement consistent with the techniques described herein.

The compute nodes 3004 are intra-connected through multiple electronic channels 3040. In particular, each compute node 3004 is connected to each adjacent compute node 3004 by one of the electronic channels 3040. In this way, the corner nodes are each connected to two adjacent nodes through two electrical channels, the edge nodes are each connected to three adjacent nodes through three electrical channels, and the interior nodes are connected to four adjacent nodes through four electrical channels. In this way, the compute nodes 3004 form an electronic network 3041 for communicating and/or transmitting messages between the compute nodes 3004 via the electronic channels 3040. Each of the compute nodes 3004 is connected either directly, e.g., to adjacent nodes, or indirectly, through one or more other nodes, to all other compute nodes 3004. The connecting of all adjacent compute nodes 3004 by the electronic channels 3040 in this way represents a maximum adjacency configuration for the electronic network 3041 in that all adjacent nodes are connected. This provides a complete, fast, and/or robust electronic network providing a maximum amount of transmission paths between nodes and/or through the network, as will be described in further detail. In this way, the electronic network 3041 may be configured in a rectangular mesh topology.

More generally, electronic networks connecting compute nodes can be configured according to other topologies. For example, one or more nodes may not be connected to all adjacent nodes, e.g., one or more of the electronic channels 3040 of the rectangular mesh topology may be omitted. For example, every node may be connected to at least one other node and may accordingly be intra-connected to all other nodes but may not necessarily be connected to each adjacent node. In a non-limiting example, each interior node may be connected to only one edge node and no other nodes. Any number of topologies for electronically intra-connecting all compute nodes 3004 without connecting all adjacent nodes are contemplated. The connecting of all nodes with a less-than-maximum adjacency configuration in this way may represent an intermediate adjacency configuration, e.g., less than all adjacent nodes connected, or even a minimum adjacency configuration, e.g., minimum number of adjacent connections to maintain connectivity of all nodes. Intra-connecting the compute nodes 3004 in a less-than-maximum adjacency configuration in this way may simplify the design, production, and/or implementation of an electronic network and/or a circuit package. For example, such a configuration may simplify determining transmission paths through the network to facilitate simpler routing of messages.

In some cases, one or more electronic channels 3040 connect non-adjacent nodes. This may be in connection with either of the maximum adjacency or less-than-maximum adjacency configurations just described. Such a configuration may increase or even maximize use of configurable electronic connections for each compute node 3004 to increase the robustness and speed of the electronic network 3041.

The intra-connection of the compute nodes 3004 in this way may facilitate transfer of messages through the electronic network 3041. For example, messages may be directly transferred between routers of any two compute nodes 3004 that are directly connected, e.g., adjacent. Message transfer between any two compute nodes 3004 that are not directly connected may also be accomplished by passing the message through one or more intervening compute nodes 3004. For example, for a message originating at node [0,3] and destined for transmittal to node [1,2], the router for node [0,3] may transmit the message to the router for node [0,2] which may then ultimately forward or transmit the message to the router for node [1,2]. Similarly, transmittal of the message could be implemented through the path [0,3]-[1,3]-[1,2]. In this way, messages may be transmitted between any two indirectly connected, e.g., non-adjacent, nodes by one or more “hops” along a path through one or more intervening compute nodes 3004 within the electronic network 3041.

As described, each of the compute nodes 3004 may be configured to connect to one or more, e.g., up to four, bidirectional photonic channels for two-way data transmission between nodes. Photonic channels are typically faster and more energy efficient than electronic channels as distance or resistance increases. As will be described with reference to the various configurations below, in some cases, compute nodes 3004 are connected through bidirectional photonic channels to leverage the speed and energy efficiency of the photonic channels for an improved network. In some cases, however, adjacent compute nodes 3004 are not intra-connected with bidirectional photonic channels, but rather are still connected through the electronic network 3041 shown and described in connection with FIG. 3-1. Implementing the electronic network 3041 in this way for adjacent connections may allow the photonic ports of each compute node 3004 to be utilized for, e.g., up to four, bidirectional photonic connections with non-adjacent nodes, and nodes included in other circuit packages as described herein. This may help to increase speed, robustness, and completeness of the network of compute nodes 3004 despite employing the slower, less-efficient electronic connections for adjacent nodes. For example, transmittal speed and energy efficiency for electronic channels typically diminishes with distance, while photonic channels can maintain a high speed and energy efficiency over longer distances. Accordingly, utilizing the electronic channels 3040 for short interconnects between adjacent or nearly adjacent nodes while implementing the faster, more energy efficient photonic connections for connections between more distant nodes can increase the overall and/or average speed of the network as well as reduce the energy consumption. In this way, implementing the electronic network 3041 may improve network performance by implementing the various configurations of the photonic channels and network topologies described below. The foregoing network configuration can allow for flexibility when code is executed on the compute nodes because software schemes, compilers, schedulers, and the like can take advantage of, and/or route data through, electronic or photonic channels in a manner most advantageous for the needs off a program that is being executed.

As is evident in the example network of FIG. 3-1, the further the separation between two nodes, the greater the number of hops and the greater the number of possible transmission paths between the two nodes. For example, to transmit a message from node [0,1] to node [3,2] at least four hops are needed. In a more extreme case, a message transmitted between node [0,0] and node [3,3], can be accomplished in no less than six hops. In some examples, one or more non-adjacent compute nodes 3004 are connected to facilitate reducing a number of hops for one or more transmission paths between the compute nodes 3004.

FIGS. 3-2 and 3-3 are each diagrams illustrating an example of the circuit package 3000 of FIG. 3-1 with multiple connections between non-adjacent compute nodes 3004. The non-adjacent connections may be implemented either separately or in connection with the adjacent connections described above with reference to FIG. 3-1.

In some examples, the circuit package 3000 includes one or more intra-chip bidirectional photonic channels 3042. The intra-chip bidirectional photonic channels 3042 are implemented in the PIC 3002. In some examples, the intra-chip bidirectional photonic channels connect one or more pairs of non-adjacent compute nodes 3004. For example, one or more of the compute nodes 3004 positioned along a periphery of the array, e.g., corner and edge nodes or “peripheral nodes”, may be connected to another peripheral node through an intra-chip bidirectional photonic channel 3042. In some examples, all of the peripheral nodes are connected to another peripheral node through an intra-chip bidirectional photonic channel 3042. In some examples, each peripheral node is connected to a peripheral node at an opposite end of the array. For example, each corner node is connected to the two corner nodes on adjacent sides of the array, such as node [0,3] being connected to node [3,3] and node [0,0]. Additionally, each edge node is connected to the (one) edge node positioned on the opposite side of the array, e.g., in a same position on the opposite side of the array. For example, edge node [2,0] is connected to edge node [2,3], and edge node [0,1] to edge node [3,1]. None of the interior nodes are connected to the intra-chip bidirectional photonic channels 3042. In this way, each side of the array may be wrapped, or connected to the opposite side of the array through the connections of the peripheral nodes by the intra-chip bidirectional photonic channels 3042.

The intra-chip bidirectional photonic channels 3042 are implemented in the PIC 3002. For example, as described above, each compute node 3004 may include one or more photonic ports in a PIC layer of the compute node 3004, and a waveguide may connect photonic ports of a pair of compute nodes 3004. In some examples, the waveguide is an internal waveguide implemented or formed in the PIC 3002. In this way the PIC 3002 may be manufactured with the waveguides included for implementing the intra-chip bidirectional photonic channels 3042. In some examples, the waveguides include an external waveguide such as an optical fiber for implementing the intra-chip bidirectional photonic channels 3042.

The intra-chip bidirectional photonic channels 3042 may be implemented in addition to the electronic channels 3040 connecting the compute nodes 3004 into the electronic network 3041. For clarity and for case of discussion, the electronic channels 3040 are not shown in FIG. 3-2 but can be seen implemented in conjunction with the intra-chip bidirectional photonic channels 3042 in FIG. 3-3. The combination of the compute nodes 3004 being connected through the electronic channels 3040 and the intra-chip bidirectional photonic channels 3042 in this way may form an electro-photonic network 3043, e.g., an intra-chip electro-photonic network. The electro-photonic network 3043 may be an intra-chip network of the compute nodes 3004 and may connect the compute nodes as a two-dimensional torus interconnect. In this way, the electro-photonic network 3043 may have a toroidal mesh topology. For example, while the compute nodes 3004 may be physically implemented in a two-dimensional planar array, each side of the plane may “wrap” around to an opposite side, e.g., left-right and top-bottom, such that the array may be connected in the shape of a torus. In this way, adjacent nodes are directly connected, and peripheral nodes are conceptually “adjacent” and directly connected to the peripheral nodes on the opposite side of the array through the intra-chip bidirectional photonic channels 3042.

A toroidal mesh topology of the electro-photonic network 3043 in this way helps to reduce an average number of hops between pairs of compute nodes 3004 in the network. In the example given above, the transmission path between node [0,1] and node [3,2] required a minimum of four hops through the electronic network 3041. By implementing the electro-photonic network 3043 including the intra-chip bidirectional photonic channels 3042, the transmission of a message from node [0,1] to node [3,2] can be accomplished in just two hops, e.g., [0,1]-[3,1]-[3,2]. Similarly, the transmission path from node [0,0] to [3,3] is reduced from six hops in the electronic network 3041 down to two hops in the electro-photonic network 3043. In this way, implementing the electro-photonic network 3043 may increase the speed, reliability, and robustness of the network of compute nodes 3004 by enabling delivery of messages through fewer hops. Additionally, the electro-photonic network 3043 may accordingly reduce an overall amount of traffic that individual routers process as a message traverses the network.

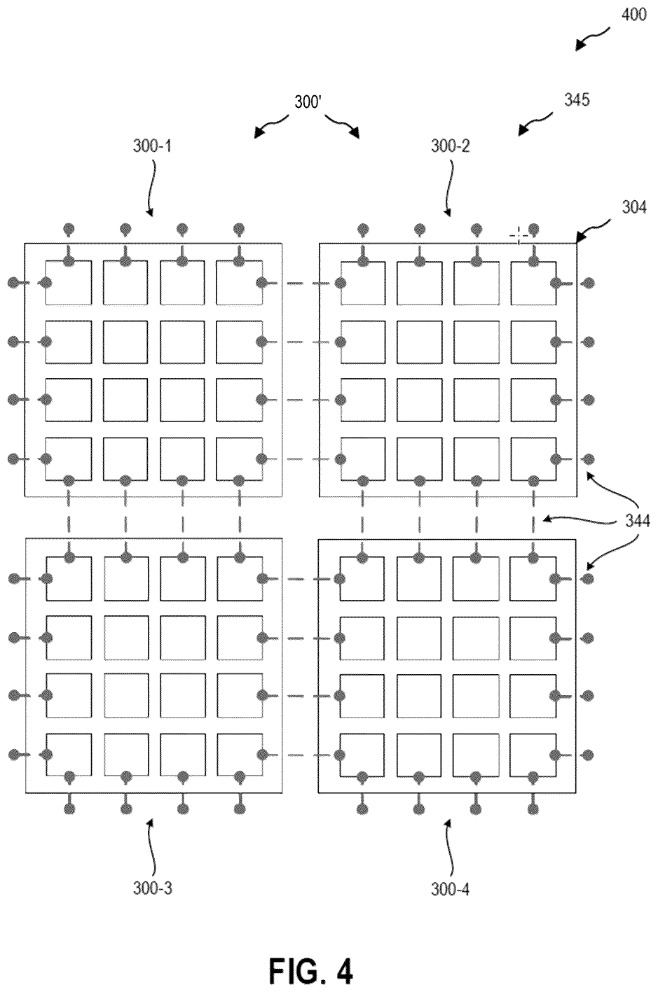

FIG. 3-4 is a diagram illustrating an example of the circuit package 3000 of FIG. 3-1 implementing multiple connections to one or more additional circuit packages. The circuit package 3000 may include one or more inter-chip bidirectional photonic channels 3044 to connect one or more of the compute nodes 3004 to one or more computing devices of other circuit package(s). The inter-chip bidirectional photonic channels 3044 may be implemented either separately or in connection with the electronic channels 3040 described above with reference to FIG. 3-1 and/or the intra-chip bidirectional photonic channels 3042 described above with reference to FIGS. 3-2 and 3-3.

In some examples, the inter-chip bidirectional photonic channels 3044 are implemented using exterior waveguides such as optical fibers. For example, an optical fiber may couple with any suitable optical interface, e.g., a FAU as described with reference to FIGS. 2-1 and 2-2, included in the circuit package 3000 to connect to the photonic port(s) of one or more compute nodes 3004 through an interior waveguide. In some examples, an optical fiber connects directly to a photonic port of one or more compute nodes 3004 without an interior waveguide. The optical fiber may have a similar connection with one or more computing devices of a separate circuit package with which it connects. For example, the optical fiber may connect two circuit packages by connecting to an FAU of each circuit package. One or more optical fibers connected in this way may form one or more unidirectional photonic links including drivers, modulators, waveguides, grating couplers, FAUs, photodiodes, and transimpedance amplifiers associated with each circuit package. In this way, the inter-chip bidirectional photonic channels 3044 may be formed using any of the components described herein with reference to FIGS. 2-1 and 2-2.

In some examples, the inter-chip bidirectional photonic channels 3044 connect to one or more of the peripheral nodes. In some examples, each of the peripheral nodes connects to an inter-chip bidirectional photonic channel 3044. For example, each corner node may connect to two inter-chip bidirectional photonic channels 3044, and each edge node may connect to one inter-chip bidirectional photonic channel 3044. The connection of the peripheral nodes in this way may facilitate connecting and/or arranging multiple circuit packages into a grid or array. For example, as will be described in further detail below, in some examples, the multiple circuit packages 3000 are connected together in an array to form a larger interconnect and/or network via the inter-chip bidirectional photonic channels 3044. In some examples, the circuit package 3000 connects to similar or complimentary circuit packages in place or in addition to connecting to identical or other instances of the circuit package 3000. In this way, the inter-chip bidirectional photonic channels 3044 may facilitate incorporating the circuit package 3000 and the compute nodes 3004 into a larger inter-chip network.

In some examples, the circuit package 3000 includes the inter-chip bidirectional photonic channels 3044 in addition to the electronic channels 3040 and the intra-chip bidirectional photonic channels 3042 described above. For clarity and for ease of discussion, only the inter-chip bidirectional photonic channels 3044 are shown in FIG. 3-4, but an implementation with all of the channels can be seen in FIG. 3-5. The combination of the compute nodes 3004 being connected through the electronic channels 3040, the intra-chip bidirectional photonic channels 3042, and the inter-chip bidirectional photonic channels 3044 in this way may form a larger, inter-chip electro-photonic network 3045. For example, the inter-chip bidirectional photonic channels 3044 may facilitate joining or connecting the (e.g., intra-chip) electro-photonic network 3043 with intra-chip networks of one or more other circuit packages into a larger, more robust network.

In the various example described and shown with reference to FIGS. 3-2 to 3-5 and other examples described herein as well, the various photonic channels, both inter-chip and intra-chip, have been depicted as connected or terminating at an edge of the compute nodes 3004. It should be understood, however, that these depictions are intended to be illustrative of the connectivity of the various components described herein and are not intended to be limiting with respect to an actual physical layout or implementation of the various components. For example, the various photonic channels may extend within or underneath the compute nodes 3004. The various channels may terminate or end at a transceiver or AMS block of the compute nodes 3004. The various channels may terminate or end at a central region or location within the compute nodes 3004. Additionally, while the compute nodes 3004 are shown as connecting to the various channels at north, cast, south, and/or west positions of the compute nodes 3004, it should be understood that this is merely illustrative and the photonic ports of the compute nodes 3004 may be located at any location with respect to the compute nodes 3004, including multiple photonic ports at the same side, e.g., north, cast, south, or west, or adjacent sides. For example, all four photonic ports of a compute node 3004 may be located at the same side of the compute node 3004.

In some examples, the circuit package 3000 is connected through inter-chip bidirectional photonic channels 3044 to one or more additional circuit packages. FIG. 4 illustrates an example implementation of four of circuit packages being interconnected. In particular, a system 400 includes circuit packages 300′ arranged in a two-dimensional array. The circuit packages 300′ include a circuit package 300-1 (top-left), 300-2 (top-right), 300-3 (bottom-left), and 300-4 (bottom-right). As shown, the peripheral compute nodes on each side of a circuit package that is adjacent a side of another circuit package may connect directly to a corresponding, adjacent node on the adjacent circuit package via inter-chip bidirectional photonic channels 344. In this way, the circuit packages 300-1 to 300-4 form a grid of 64 compute nodes 304 arranged in eight rows of eight adjacent and directly connected compute nodes 304.

In some examples, each of the circuit packages 300′ include the electronic connections between adjacent nodes and/or the intra-chip bidirectional photonic channels between peripheral nodes. For clarity, such connections are not shown in FIG. 4. In this way, the benefits described above of the intra-connectivity of the compute nodes 304 within a single circuit package may similarly be applied to the inter-connectivity of multiple circuit packages 300′ into a larger, inter-chip network. For example, what would take 10 hops through adjacent nodes to transmit a message from the top-left node of circuit package 300-1 to the bottom-right node of circuit package 300-2 may be achieved in 4 hops by utilizing the intra-chip bidirectional photonic channels connecting peripheral nodes within each circuit package as described above.

As shown, all of the peripheral nodes of each circuit packages 300′ are connected to one or more inter-chip bidirectional photonic channels 344. For example, in addition to adjacent sides of the circuit packages 300′ being directly connected, one or more of the peripheral nodes on non-adjacent sides (e.g., on a periphery of the inter-chip grid) may also be directly connected to other nodes. Any number of configurations or topologies of the inter-chip electro-photonic network may be contemplated by inter-connecting nodes with the inter-chip bidirectional photonic channels 344. Such configurations may reduce and/or minimize a number of hops between pairs of compute nodes by leveraging the configurability of each compute node to connect to two or more photonic channels; in this example four are shown. In this way, high network efficiency and flexibility for various routing schemes, depending on the algorithm being executed, may be maintained even for networks implementing multiple circuit packages and/or large numbers of compute nodes.

### Optical Modulator Drivers

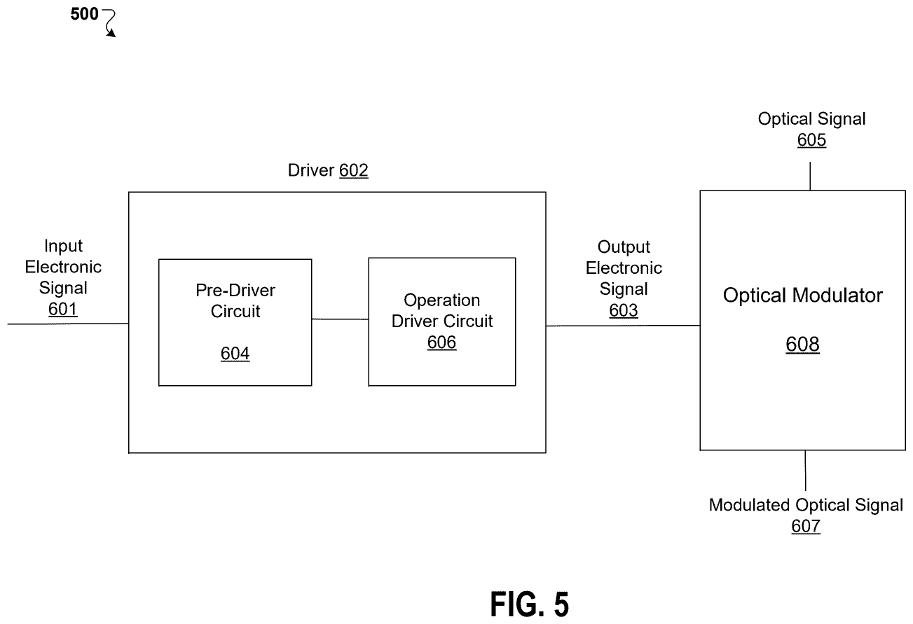

FIG. 5 is a diagram illustrating an example 500 of a driver 602 for an optical modulator 608. The optical modulator 608 can be implemented as the optical modulator 356-1, 356-2 of FIG. 2-1 or 356 of FIG. 2-2. For example, the optical modulator 608 can include an EAM based on Franz-Keldysh (FK) effect or quantum confined stark effect (QCSE). The driver 602 can be an optical modulator driver implemented as the driver 362-1, 362-2 of FIG. 2-1 or 362 of FIG. 2-2. The optical modulator 608 and the driver 602 can form an EO interface, e.g., the EO interface 124 of FIG. 1-2 or 1-3, to facilitate optically transmitting messages. The driver 602 can be arranged in an EIC, e.g., the EIC 101-1 of FIG. 1-2, or 1401 of FIG. 1-4, 301 of FIG. 2-1 or 2-2, and the optical modulator 608 can be arranged in a PIC, e.g., the PIC 102-1 of FIG. 1-2, 1402 of FIG. 1-4, or 302 of FIG. 2-1 or 2-2. The driver 602 and the optical modulator 608 can be stacked together and coupled through an electronic interconnect, e.g., copper pillar or stud pump, between the EIC and the PIC, e.g., as illustrated in FIG. 1-4, FIG. 2-1, or FIG. 2-2. The driver 602 can be positioned adjacent to the electronic interconnect.

The driver 602 can receive an input electronic signal 601, e.g., data packet encoded into an electronic signal, from a message router, e.g., the message router 110 of FIG. 1-1 or 1-2, and output an output electronic signal 603 to drive or control the optical modulator 608. The optical modulator 608 can modulate an optical signal 605 with the output electronic signal 603 to generate a modulated optical signal 607. The optical signal 605 can be an optical carrier signal, e.g., laser light. The optical modulator 608 can convert or encode the output electronic signal 603 into the optical signal 605.

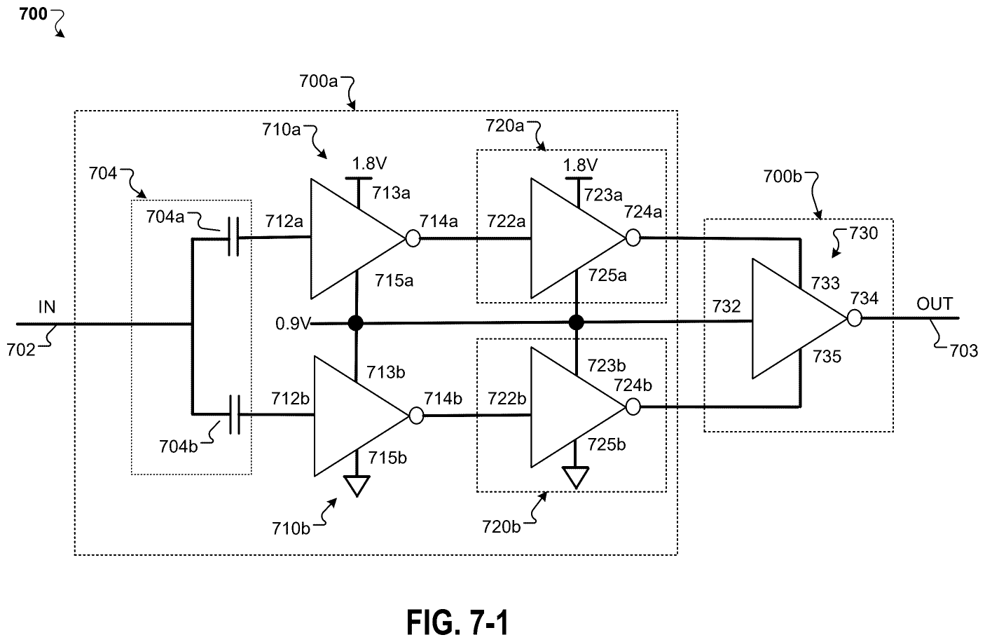

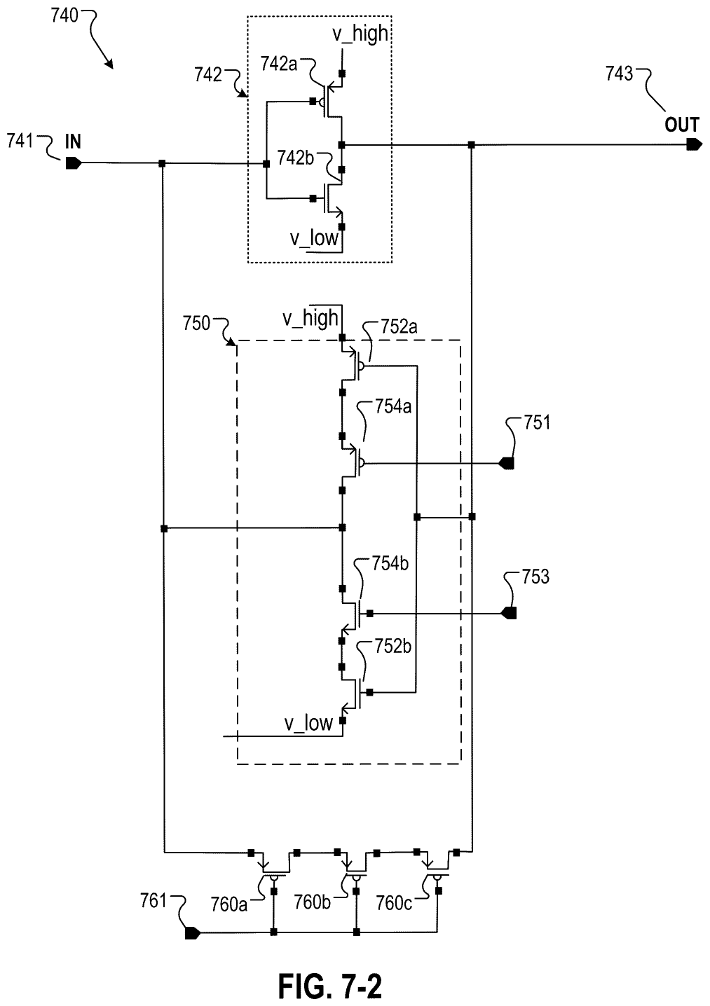

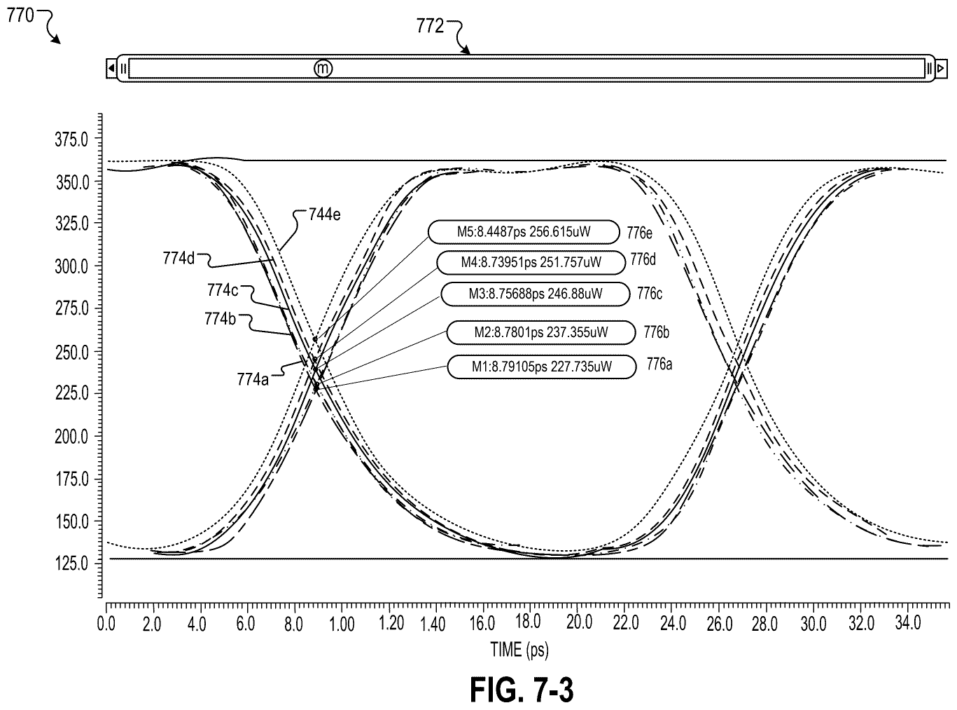

In some examples, the modulated optical signal 607 can be used to form an optical eye diagram, e.g., as illustrated in FIG. 7-3, which can show one or more characteristics of the modulated optical signal 607. With different voltage profiles of the input electronic signal 601, the modulated optical signal 607 can represent different data information. In some examples, the modulated optical signal 607 has two non-return-to-zero (NRZ) levels with a throughput of 1 bit per Unit Interval (UI), e.g., as illustrated in FIG. 7-3. The modulated optical signal 607 can vary between a higher signal level representing bit “1” and a lower signal level representing bit “0”. In some examples, the modulated optical signal has four complementary pulse-amplitude-modulation (PAM4) levels with a throughput of 2 bits per Unit Interval (UI). In some examples, a UI can be 17 picoseconds (ps), and the driver 602 and/or the optical modulator 608 can have a speed of about 58.8 G bits per second (Gbps). The modulated optical signal 607 can vary between four signal levels respectively representing bits “10”, “11”, “01”, “00”.

In some examples, e.g., as illustrated in FIG. 7-3, rising edges and falling edges of the modulated optical signal 607 can form an eye shape. A larger eye represents a better quality signal. The greater the eye height between adjacent signal levels, the better the quality of the modulated optical signal. Crosspoints between the rising edges and the falling edges of the modulated optical signal 607 may vary between the adjacent signal levels. If the rising edges and the falling edges are symmetric, the crosspoint can be at a middle of the adjacent signal levels. The positions of the crosspoints can affect how accurately a receiver, e.g., a photodiode and a transimpedance amplifier, detects bit information represented in the modulated optical signal 607.

In some examples, the optical signal 605 includes one or more laser pulses. A laser pulse may have a sharper rising edge than a falling edge, or a shorter rising time and slower falling time, which can cause the rising edge and the falling edge of the modulated optical signal 608 to be asymmetric. Also, the optical modulator 608 is generally nonlinear, which can also cause a difference between the rising edge and the falling edge of the modulated optical signal 608. Further, different optical modulators may have different device characteristics, e.g., nonlinearity, and can have different responses to a same electronic signal.

Techniques will now be described that improve a performance of the optical modulator 608 and the driver 602, e.g., increasing transmission speed and/or bandwidth, improving signal to noise ratios (SNRs) or reducing bit error rates (BERs), minimizing parasitic of the driver and/or the optical modulator, and/or achieving low power consumption or dissipation.

In some examples, the driver 602 includes an operation driver circuit 606 coupled to a pre-driver circuit 604. The operation driver circuit 606 can be configured to operate when a device that includes the driver 602 and the optical modulator 608 is active. The operation driver circuit 606 can be a high performance driver and can be active whenever a compute node is working and providing data packets to the driver for sending to a destination across a photonic channel. Here, “high performance” refers to the speed of the driver, i.e., fast rise/fall time of the waveform; fast charging and discharging of load and parasitic capacitances. The high performance driver modulates the optical modulator 608 to generate a modulated optical signal that represents data that is being sent/provided to a transmitter, e.g., the driver 602 and the optical modulator 608, by a digital interface from a computing unit or device, e.g., CPU or GPU.

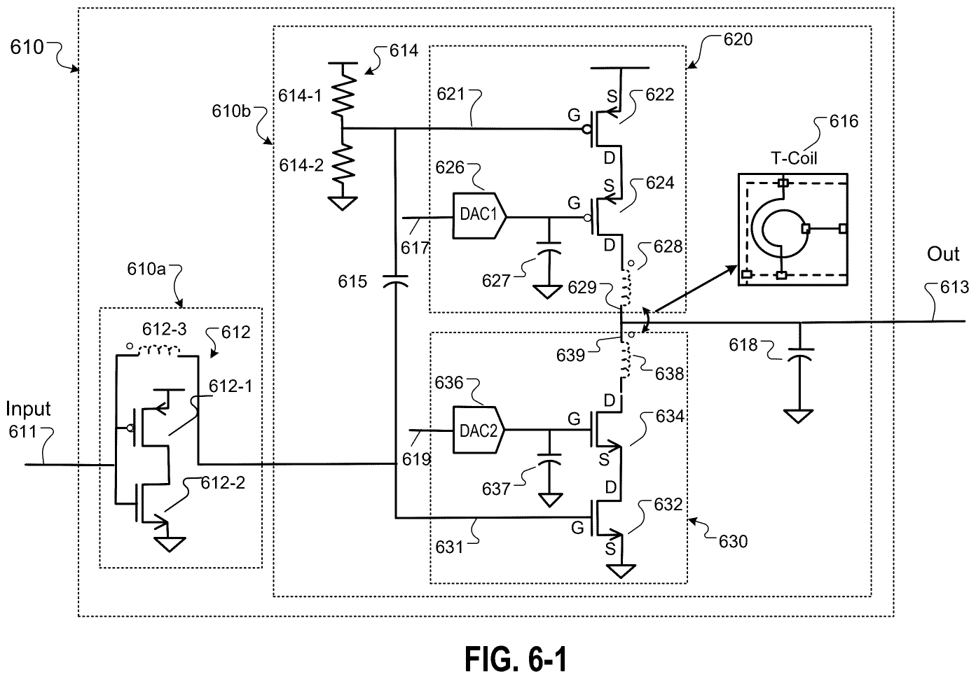

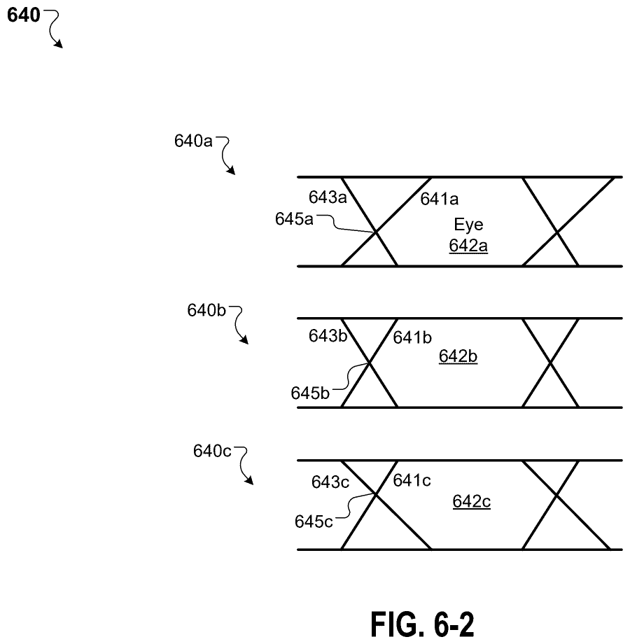

As described with further details in reference to FIG. 6-1, the driver 602 can be configured such that data is loaded into a high speed path, and switches can regulate how strong the high speed path is, without causing additional loading when the switches are turned off. Here, the strength of the high speed path refers to circuit's ability to drive current, i.e., how much current a switch provides when turned on via its gate voltage. A switch can include a transistor, and a gate voltage of the transistor can be controlled, e.g., changeably and digitally, by a control circuit that can be a digital-to-analog converter (DAC) connected to receive a digital input signal and convert the digital input signal into an analog signal to the switch. The switch regulates how strong the high speed path is based on the digital input signal that can adjust a rising time of the rising edge of the output electronic signal 603 and/or a falling time of the falling edge of the output electronic signal 603. In such a way, the rising edge and the falling edge of the output electronic signal 603 from the driver 602 can be adjusted, e.g., pre-distorted with respect to the rising edge and the falling edge of the modulated optical signal 607, thereby adjusting the properties of the modulated optical signal 607, e.g., controlling the eye shape that is received by the receiver, as illustrated with further details in FIG. 6-2.

In some examples, the driver 602 includes a pre-driver circuit 604 that can calibrate the optical modulator 608, e.g., when the optical modulator 608 is booted, such that the crosspoints detected by a receiver are in a middle position between a higher signal level and a lower signal level, and such that the receiver can read the signal with minimized error bits. As described with further details in reference to FIGS. 7-1 to 7-3, the pre-driver circuit 604 can be configured to make the optical eye, or the rising edge and the falling edge of the modulated optical signal 607, symmetric or the crosspoint in the middle by pre-distorting the output electronic signal 603 based on known characteristics or expected characteristics of the optical modulator 608. The pre-driver circuit 604 can also be digitally controlled to move the crosspoints up and down. The calibration information of the pre-driver circuit 604 can be provided to the operation driver circuit 606 when the operation driver circuit 606 is active.

FIG. 6-1 is a circuit diagram illustrating an example of a driver 610 for an optical modulator or an optical modulator driver. The driver can be implemented as the driver 602 of FIG. 5. The optical modulator can be, e.g., the optical modulator 608 of FIG. 5.

In some examples, as shown in FIG. 6-1, the driver 610 includes a pre-driver circuit 610a and an operation driver circuit 610b coupled to the pre-driver circuit 610a. The pre-driver circuit 610a can be used as the pre-driver circuit 604 of FIG. 5. The operation driver circuit 610b can be used as the operation driver circuit 606 of FIG. 5.

The driver 610 includes an input 611 for receiving an input signal, e.g., the input electronic signal 601 of FIG. 5, and an output 613 for outputting an output signal, e.g., the output electronic signal 603 of FIG. 5. The output signal of the driver 610 can be determined based on properties of the optical modulator, e.g., EAM. For example, based on an absorption curve of the optical modulator, optical modulation can be achieved by electrically modulating the optical modulator within an input between 0 and Vₘₐₓ. e.g., 1.8 V. In some examples, the input signal has an initial voltage swing, e.g., from 0 to Vₘₐₓ/2 such as 0 to 0.9 V, and the operation driver circuit 610 can be configured to cause the output signal with a desired or target voltage swing, e.g., from 0 to Vₘₐₓ such as 0 to 1.8 V. The voltage Vₘₐₓ can be determined from the absorption curve of the optical modulator. Note that the voltage Vₘₐₓ can be any suitable voltage for the optical modulator, e.g., 1.0 V, 1.2 V, 1.4 V, 1.6 V, 1.8 V, 2.0 V, 2.2 V, 2.4 V, 2.6 V. 2.8 V, 3.0 V, or higher. For illustration, 1.8 V is used as an example of Vₘₐₓ.

In some examples, the operation driver circuit 610b can include a first operation circuit 620 and a second operation circuit 630 that are symmetric. The first operation circuit 620 and the second operation circuit 630 can be operated in parallel. The pre-driver circuit 610a can include an input circuit 612 coupled to the first operation circuit 620 and the second operation circuit 630. The input circuit 612 can generate a first input signal for the first operation circuit 620 and a second input signal for the second operation circuit 630 based on the input signal. The first input signal can have a first voltage swing, e.g., Vₘₐₓ/2 to Vₘₐₓ such as 0.9 V to 1.8 V, and the second input signal can have a second voltage swing, e.g., 0 to Vₘₐₓ/2 such as 0 to 0.9 V.

In some examples, e.g., as illustrated in FIG. 6-1, the input circuit 612 includes a pair of a p-type transistor 612-1 and an n-type transistor 612-2, and an inductor 612-3. The p-type transistor 612-1 can be a P-Channel Metal-Oxide Semiconductor (PMOS) transistor, and the n-type transistor 612-2 can be an N-Channel Metal-Oxide-Semiconductor (NMOS) transistor. In some examples, the driver 610, e.g., the operation driver circuit 610b, further includes a voltage divider 614 including two resistors 614-1, 614-2 coupled in series between a higher supply voltage, e.g., 1.8 V, and a lower supply voltage, e.g., 0 V. The first operation circuit 620 can be coupled to a connection between the two resistors.

The operation driver circuit 610b can include a capacitor 615 coupled between a first input 621 of the first operation circuit 620 and a second input 631 of the second operation circuit 630. Gate terminals of the p-type transistor 612-1 and the n-type transistor 612-2 receive the input signal at the input 611. Drain terminals of the p-type transistor 612-1 and the n-type transistor 612-2 are coupled to the second input 631 of the second operation circuit 630. The inductor 612-3 is coupled between the gate terminals and the drain terminals. As noted above, the input signal has the initial voltage swing, and the second voltage swing of the second input signal can be identical to the initial voltage swing. For example, the first voltage swing of the first input signal is between a first lower voltage, e.g., 0.9 V, and a first higher voltage, e.g., 1.8 V. The second voltage swing of the second input signal can be between a second lower voltage, e.g., 0 V, and a second higher voltage, e.g., 0.9 V. A source terminal of the p-type transistor 612-1 can be coupled to a first supply voltage, e.g., 1.8 V, identical to the first higher voltage, and a source terminal of the n-type transistor 612-2 can be coupled to a second supply voltage, e.g., 0 V, identical to the second lower voltage.

In some examples, the input circuit 612 includes a voltage divider circuit that can convert the input signal with an initial voltage swing, e.g., 0 to 0.9 V or 0 to 1.8 V, into the first input signal with the first voltage swing, e.g., 0.9 to 1.8 V, for the first operation circuit 620 and the second input signal with the second voltage swing, e.g., 0 to 0.9 V, for the second operation circuit 630.

In some examples, the first operation circuit 620 has the first input 621 for receiving the first input signal, a first output 629 coupled to the output 613 of the driver 610, and a first switch 624 coupled between the first input 621 and the first output 629. Similarly, the second operation circuit 630 has the second input 631 for receiving the second input signal, a second output 639 coupled to the output 613, and a second switch 634 coupled between the second input 631 and the second output 639.

The first operation circuit 620 can be at least part of a first signal path, e.g., a PMOS signal path. The second operation circuit 630 can be at least part of a second signal path, e.g., an NMOS signal path. In some examples, the first switch 624 can be connected to receive a first voltage control signal that is adjustable to control the first signal path with the first input signal. The second switch 634 can be connected to receive a second voltage control signal that is adjustable to control the second signal path with the second input signal. The first operation circuit 620 and the second operation circuit 630 can be configured to control a rising edge and a falling edge of the output signal at the output 613. For example, the first operation circuit 620 can be configured to independently control the rising edge of the output signal at the output 613, and the second circuit can be configured to independently control the falling edge of the output signal at the output 613. The output signal can be based on a first output signal at the first output of the first operation circuit 620 and a second output signal at the second output of the second operation circuit 630.

In some examples, the first operation circuit 620 includes a first p-type transistor 622. The first p-type transistor 622 can be a PMOS transistor. The first p-type transistor 622 includes a gate terminal (G) coupled to the first input for receiving the first input signal, a source terminal (S) coupled to a first supply voltage, e.g., 1.8 V, and a drain terminal (D) coupled to the first switch 624. The first switch 624 can include a second p-type transistor 624 that includes a gate terminal configured to receive the first voltage control signal, a source terminal coupled to the drain terminal for the first p-type transistor 622, and a drain terminal coupled to the output 613.

Similarly, the second operation circuit 630 can include a first n-type transistor 632. The first n-type transistor 632 can be an NMOS transistor. The first n-type transistor 632 can include a gate terminal coupled to the second input for receiving the second input signal, a source terminal coupled to a second supply voltage, e.g., 0 V, and a drain terminal coupled to the second switch 634. The first supply voltage is higher than the second supply voltage. The second switch 634 can include a second n-type transistor 634 that can include a gate terminal configured to receive the second voltage control signal, a source terminal coupled to the drain terminal for the first n-type transistor 632, and a drain terminal coupled to the output 613.

In some examples, the operation driver circuit 610b includes a pair of inductors 628, 638 coupled between the first output of the first operation circuit 620 and the second output of the second operation circuit 630 and the output 613 of the operation driver circuit 610. For example, the inductor 628 can be coupled between the drain terminal of the second p-type transistor 634 and the output 613, and the inductor 638 can be coupled between the drain terminal of the second n-type transistor 634 and the output 613. The inductors 628, 638 can be inductively coupled with each other. The inductors 628, 638 can be arranged to maximize a coupling area, thereby improving a coupling efficiency.

In some examples, the pair of inductors 628, 638 can form a T-coil 616, e.g., as illustrated in FIG. 6-1, that can have inputs respectively coupled to the first output of the first operation circuit 620 and the second output of the second operation circuit 630 and an output coupled to the output 613. In some examples, the T-coil 616 includes two windings of metal lines arranged with respect to each other in a same layer. In some examples, the T-coil 616 includes two metal layers functioning as the inductors 628 and 638 respectively in a stacked configuration. The inductances of the inductors 628 and 638 can be configured to be symmetric across frequency. The inductors 628 and 638 in the T-coil 616 can increase an output impedance of the operation driver circuit 610b and/or the driver 610 at higher frequencies, leading to an over-peaked response. The T-coil 616 can also be configured to ensure that a parasitic capacitance in the first signal path can be minimized during a 1 to 0 transition and a parasitic capacitance in the second signal path can be minimized during a 0 to 1 transition, which can reduce self-loading and improve a bandwidth of the operation driver circuit 610.

In some examples, the first voltage control signal for the first switch 624 has a first series of discrete analog voltages, and the second voltage control signal for the second switch 634 has a second series of discrete analog voltages. In some examples, the first operation circuit 620 includes a first control circuit, e.g., a first digital to analog converter (DAC) 626, coupled to the first switch 624, e.g., the gate terminal of the second p-type transistor 624, and the first DAC 626 converts a first control signal 617, e.g., a first digital signal, into the first voltage control signal. The first DAC 626 can receive the first digital signal from a controller, e.g., a compute block such as block 358-1 or 358-2 of FIG. 2-1 or 358 of FIG. 2-2. The first voltage control signal can be changed by a change of the first digital signal by the controller. The second operation circuit 630 can include a second DAC 636 coupled to the second switch 634, e.g., the gate terminal of the second n-type transistor 634, and the second DAC 636 converts a second control signal 619, e.g., a second digital signal, into the second voltage control signal. The second DAC 636 can receive the second digital signal from the controller, e.g., the compute block such as 358-1, 358-2 of FIG. 2-1 or 358 of FIG. 2-2. The second voltage control signal can be changed by a change of the second digital signal by the controller. The first and second digital control signals 617, 619 can each be an 8-bit digital value. In this way, the first operation circuit 620 and the second operation circuit 630 can be independently and digitally controlled. In some examples, the controller is configured to directly provide the first voltage control signal, e.g., with the first series of discrete analog voltages, to the first switch 624 and/or the second voltage control signal, e.g., with the second series of discrete analog voltages, to the second switch 634.

As described above, the output 613 of the driver 610 can be electrically coupled to the optical modulator to provide the output signal to the optical modulator for modulating an optical signal. In some examples, the output 613 can be coupled to a capacitor 618, e.g., that is grounded.

A rising edge of the optical signal can be sharper than a falling edge of the optical signal. Such asymmetric properties of the optical signal can be the result of non-linear characteristics of the laser source. To compensate the asymmetric edges of the optical signal and make edges of the modulated optical signal be symmetric, the first operation circuit 620 and the second operation circuit 630 can be configured such that the falling edge of the output signal of the driver 610 is sharper than the rising edge of the output signal to compensate a difference between the rising edge and the falling edge of the optical signal. For example, values of the first control signal 617 are set to the switch 624 in the first operation circuit 620 can independently control the first signal path to cause the rising time of the rising edge of the output signal at the output 613 to be longer, i.e., the rising edge being less sharp, and values of the second control signal 619 are set to the switch 634 in the second operation circuit 630 can independently control the second signal path to cause the falling time of the falling edge of the output signal at the output 613 to be shorter. This is done so that a rising edge and a falling edge of the modulated optical signal are symmetric, e.g., as illustrated in FIG. 6-2. In some examples, the modulated optical signal varies between a higher level, e.g., representing bit “1”, and a lower level, e.g., representing bit “0”, and the modulated optical signal defines a crosspoint between a corresponding rising edge and a corresponding failing edge of the modulated optical signal. As noted below, by setting the respective values of the first control signal 617 and the second control signal 619, the first operation circuit 620 and the second operation circuit 630 can be controlled to move the crosspoint between the higher level and the lower level, e.g., as illustrated in FIG. 6-2. The first operation circuit 620 and the second operation circuit 630 can be controlled to move the crosspoint to move to a middle between the higher level and the lower level.

FIG. 6-2 is a diagram illustrating an example 640 of operating the driver 610 of FIG. 6-1 to control optical eye diagrams. As diagram 640b shows, when a rising edge 641b and a falling edge 643b of the modulated optical signal are symmetric, a crosspoint 645b of the rising edge 641b and the failing edge 643b is in a middle of a higher level and a lower level, and an eye shape 642b can be symmetric, too. As diagram 640a shows, when a falling edge 643a is sharper than a rising edge 641a, a corresponding crosspoint 645a is lower than the middle of the higher level and the lower level, and an eye shape 642a is asymmetric. As diagram 640c shows, when a rising edge 641c is sharper than a falling edge 643c, a corresponding crosspoint 645c is higher than the middle of the higher level and the lower level, and an eye shape 642c is asymmetric. As described above, the first operation circuit 620 and the second operation circuit 630 can be configured, e.g., by separately controlling the first switch 624 and the second switch 634 with respective values set for the first control signal 617 and the second control signal 619, to control the falling edge and the rising edge of the output signal to thereby control the falling edge and the rising edge of the modulated optical signal.

FIG. 7-1 is a diagram illustrating another example of a driver 700 for an optical modulator. The driver 700 is configured to calibrate the optical modulator to make an eye diagram symmetric or a corresponding crosspoint in a middle between adjacent signal levels.

The driver can be implemented as the driver 602 of FIG. 5. The optical modulator can be, e.g., the optical modulator 608 of FIG. 5. In some examples, as shown in FIG. 7-1, the driver 700 includes a pre-driver circuit 700a and an operation driver circuit 700b coupled to the pre-driver circuit 700a. The pre-driver circuit 700a can have a stacked inverter structure. The pre-driver circuit 700a can be implemented as the pre-driver circuit 604 of FIG. 5. The operation driver circuit 700b can be implemented as the operation driver circuit 606 of FIG. 5.

In some examples, as shown in FIG. 7-1, the driver 700 includes an input 702 for receiving an input signal, e.g., the input electronic signal 601 of FIG. 5, and an output 703 for outputting an output signal, e.g., the output electronic signal 603 of FIG. 5. The output 703 of the driver 700 can be electrically coupled to the optical modulator to provide the output signal to the optical modulator for modulating an optical signal based on the output signal. In some examples, the input signal has an initial voltage swing, e.g., from 0 to 0.9 V, and the driver 700 can be configured to cause the output signal with a desired or target voltage swing, e.g., from 0 to 1.8 V, for the optical modulator.

In some examples, the pre-driver circuit 700a includes a first inverting circuit 710a having a first input 712a for receiving a first input signal and a first output 714a coupled to a first input of the operation driver circuit 700b that is coupled to the output 703 of the driver 700, and a second inverting circuit 710b having a second input 712b for receiving a second input signal and a second output 714b coupled to a second input of the operation driver circuit 700b that is coupled to the output 703 of the driver 700. The first inverting circuit 710a and the second inverting circuit 710b can be symmetric and function as a first signal path and a second signal path, respectively.

The first inverting circuit 710a and the second inverting circuit 710b can be operated in parallel and/or can independently control a rising edge and a falling edge of the output signal. The first inverting circuit 710a and the second inverting circuit can be configured to control the output signal at the output 703, and the output signal can be based on a first output signal at the first output 714a and a second output signal at the second output 714b. The second input signal can be different from the first input signal, and the second output signal can be different from the first output signal. For example, the second input signal and the second output signal can have a same voltage swing as the input signal, e.g., 0 to 0.9 V, and the first input signal and the first output signal can have a voltage swing different from the input signal, e.g., 0.9 V to 1.8 V.

In some examples, the first input signal to the first inverting circuit 710a includes a first voltage swing between a first higher voltage, e.g., 1.8 V, and a first lower voltage, e.g., 0.9 V, and the second input signal to the second inverting circuit 710b includes a second voltage swing between a second higher voltage, e.g., 0.9 V, and a second lower voltage, e.g., 0 V. The first lower voltage can be identical to or higher than the second higher voltage.

In some examples, the pre-driver circuit 700a includes an input circuit 704 coupled between the input 702 and the first inverting circuit 710a and the second inverting circuit 710b. The input circuit 704 can be configured to receive the input signal at the input 702 and output the first input signal to the first inverting circuit 710a and the second input signal to the second inverting circuit 710b.

In some examples, the input circuit 704 includes a voltage divider circuit that can convert the input signal with an initial voltage swing, e.g., 0 to 1.8 V, into the first input signal with the first voltage swing, e.g., 0.9 to 1.8 V, for the first inverting circuit 710a and the second input signal with the second voltage swing, e.g., 0 to 0.9 V, for the second inverting circuit 710b.

In some examples, the input circuit 704 includes a first capacitor 704a coupled between the input 702 and the first input 712a of the first inverting circuit 710a and a second capacitor 704b coupled between the input 702 and the second input 712b of the second inverting circuit 710b. The input signal has a voltage swing, e.g., 0 to 0.9 V, identical to the second voltage swing, e.g., 0 to 0.9 V, and the first lower voltage, e.g., 0.9 V, is identical to the second higher voltage. The first inverting circuit 710a can be configured to receive a first supply voltage, e.g., 1.8 V, identical to the first higher voltage and a second supply voltage, e.g., 0.9 V, identical to the first lower voltage. The second inverting circuit 710b can be configured to receive a third supply voltage, e.g., 0.9 V, identical to the second higher voltage and a fourth supply voltage, e.g., 0 V, identical to the second lower voltage.

In some examples, at least one of the first inverting circuit 710a or the second inverting circuit 710b includes an inverter coupled between a corresponding input and a corresponding output and a feedback circuit coupling the corresponding output back to the corresponding input. The feedback circuit can be configured to control an inversion strength from a corresponding input signal to a corresponding output signal to adjust the output signal and the modulated optical signal. For example, the first inverting circuit 710a can include the feedback circuit to control a strength of the first signal path, and the second inverting circuit 710b can include the feedback circuit to control a strength of the second signal path. The first inverting circuit 710a and the second inverting circuit 710b can have a same circuit structure. In some examples, the first inverting circuit 710a and the second inverting circuit 710b have different circuit structure. For example, one of the first inverting circuit 710a and the second inverting circuit 710b includes an inverter and a feedback circuit, and the other one of the first inverting circuit 710a and the second inverting circuit 710b includes an inverter, without a feedback circuit.

FIG. 7-2 is a circuit diagram illustrating an example of an inverting circuit 740. The inverting circuit 740 can be implemented as the first inverting circuit 710a or the second inverting circuit 710b or each of them.

The inverting circuit 740 includes an inverter 742 coupled between a corresponding input 741, e.g., the first input of the first inverting circuit 710a or the second input of the second inverting circuit 710b, and a corresponding output 743, e.g., the first output of the first inverting circuit 710a or the second output of the second inverting circuit 710b. The inverter 742 can include a first p-type transistor, e.g., PMOS transistor, 742a and a first n-type transistor, e.g., NMOS transistor, 742b that are coupled together. Gate terminals of the first p-type transistor 742a and the first n-type transistor 742b receive the corresponding input signal, e.g., the first input signal or the second input signal. Drain terminals of the first p-type transistor 742a and the first n-type transistor 742b are coupled to the corresponding output 743. The corresponding output 743 outputs a corresponding output signal, e.g., the first output signal or the second output signal.

In some examples, a source terminal of the first p-type transistor 742a is configured to receive a higher supply voltage and a source terminal of the first n-type transistor 742b is configured to receive a lower supply voltage. If the inverting circuit 740 is the first inverting circuit 710a, the higher supply voltage and the lower supply voltage are identical to a first higher voltage and a first lower voltage of a voltage swing of the first output signal, e.g., 1.8 V and 0.9 V, respectively. If the inverting circuit 740 is the second inverting circuit 710b, the higher supply voltage and the lower supply voltage are identical to a second higher voltage and a second lower voltage of a voltage swing of the second output signal, e.g., 0.9 V and 0 V, respectively.

In some examples, the inverting circuit 740 further includes a feedback circuit 750 coupled between the corresponding input 741 and the corresponding output 743. In some examples, the feedback circuit 750 includes a first pair of a second p-type transistor 752a, e.g., PMOS transistor, and a second n-type transistor 752b, e.g., NMOS transistor. Gate terminals of the first pair of the second p-type transistor 752a and the second n-type transistor 752b are coupled to the corresponding output 743. Drain terminals of the first pair of the second p-type transistor 752a and the second n-type transistor 752b are coupled to the corresponding input 741. A source terminal of the second p-type transistor 752a can be configured to receive the higher supply voltage, and a source terminal of the second n-type transistor 752b can be configured to receive the lower supply voltage.

The feedback circuit 750 can be configured to control an inversion strength from the corresponding input signal to the corresponding output signal. For example, when the corresponding input signal is changing from a higher voltage to a lower voltage, the first p-type transistor 742a is turned on and the first n-type transistor 742b can be turned off, and the corresponding output signal becomes higher as the first p-type transistor 742a is coupled to the higher supply voltage. Consequently, the higher corresponding output signal turns off the second p-type transistor 752a and turns on the second n-type transistor 752b. As the second n-type transistor 752b is coupled to the lower supply voltage, the corresponding input signal can be pulled down to a lower voltage by the feedback circuit 750. Thus, the inversion strength is increased by the feedback circuit 750.

Similarly, when the corresponding input signal is changing from a lower voltage to a higher voltage, the first p-type transistor 742a is turned off and the first n-type transistor 742b is turned on, and the corresponding output signal becomes lower as the first n-type transistor 742a is coupled to the lower supply voltage. Consequently, the lower corresponding output signal turns on the second p-type transistor 752a and turns off the second n-type transistor 752b. As the second p-type transistor 752a is coupled to the higher supply voltage, the corresponding input signal can be pulled up to a higher voltage by the feedback circuit 750. Thus, the inversion strength is also increased by the feedback circuit 750.

In some examples, the feedback circuit 750 further includes one or more additional pairs of a second p-type transistor and a second n-type transistor. The one or more second p-type transistors of the one or more additional pairs can be coupled in series between the drain terminal of the second p-type transistor of the first pair and the corresponding input, and the one or more second n-type transistors of the one or more additional pairs can be coupled in series between the drain terminal of the second n-type transistor of the first pair and the corresponding input. A gate terminal of at least one of the one or more second p-type transistors or the one or more second n-type transistors can be configured to receive a control signal to adjust the inversion strength. The feedback circuit 750 can include a number of pairs including the first pair and the one or more additional pairs. In some examples, the number is an even positive integer. In some examples, the number is 2^{N}, e.g., 2, 4, 8, 16, . . . ), where N is a positive integer. The feedback circuit 750 can thus be configured to adjust the inversion strength with multiple levels with an increment of 2^{-N} of a maximum strength per level.

For example, as illustrated in FIG. 7-2, the feedback circuit 750 includes one additional pair of a second p-type transistor 754a and a second n-type transistor 754b. A source terminal of the second p-type transistor 754a is coupled to the drain terminal of the second p-type transistor 752a, a drain terminal of the second p-type transistor 754a is coupled to the corresponding input 741, and a gate terminal of the second p-type transistor 754a is configured to receive a first control signal 751. A source terminal of the second n-type transistor 754b is coupled to the drain terminal of the second n-type transistor 752b, a drain terminal of the second n-type transistor 754b is coupled to the corresponding input 741, and a gate terminal of the second n-type transistor 754b is configured to receive a second control signal 753.

Thus, the feedback circuit 750 includes two pairs of second p-type transistor, e.g., 752a, 754a, and second n-type transistor, e.g., 752b, 754b, a total of four transistors. The feedback circuit 750 can be configured to control the inversion strength with multiple levels, e.g., 4 levels, based on the first control signal 751 and the second control signal 753, e.g., by turning on or off and/or modifying the strength of the pull-up p-type transistors, e.g., 752a, 754a, or the pull-down n-type transistors, e.g., 752b, 754b. For example, with four transistors in the feedback circuit 750, the inversion strength can be set to 25%, 50%, 75%, or 100%. When the feedback circuit 750 includes more pairs of p-type transistors and n-type transistors, an increment of the inversion strength per level can be more granular, while the more pairs may slow down the inversing circuit 740.

In some examples, a control signal, e.g., the first control signal 751 or the second control signal 753, to the feedback circuit 750 can be generated by a digital to analog converter (DAC) based on a digital signal, such that the output signal can be adjusted by the digital signal.

In some examples, the inverting circuit 740 includes one or more transistors, e.g., 760a, 760b, 760b, coupled in series between the corresponding input and the corresponding output. A gate terminal of each of the one or more transistors can be connected to receive a control signal 761 that controls the one or more transistors to be on or off, to control a loading of the feedback circuit 750 and to thereby affect an inversion strength of the feedback circuit 750. The control signal 761 is used to modulate the inversion and hence the effective drain-source impedance (“on resistance”) of the transistors. This allows for controlling the gain as well the input common-mode of each half (upper and lower) of the driver circuit.

In reference to FIG. 7-1, the first inverting circuit 710a includes a second input 713a, e.g., the source terminal of the first p-type transistor 742a, coupled to a higher power supply, e.g., 1.8 V, and a third input 715a, e.g., the source terminal of the first n-type transistor 742b, coupled to a lower power supply, e.g., 0.9 V. Similarly, the second inverting circuit 710b includes a second input 713b, e.g., the source terminal of the first p-type transistor 742a, coupled to a higher power supply, e.g., 0.9 V, and a third input 715b, e.g., the source terminal of the first n-type transistor 742b, coupled to a lower power supply, e.g., 0 V. Note that the first inverting circuit 710a and the second inverting circuit 710b are configured to provide first and second different voltage swings, and accordingly, the higher power supply and the lower supply voltage of the first inverting circuit 710a correspond to the first voltage swing, and the higher power supply and the lower supply voltage of the second inverting circuit 710b correspond to the second voltage swing.

In some examples, the pre-driver circuit 700a further includes an optional second inverter 720a coupled between the first inverting circuit 710a and the operation driver circuit 700b, and the second inverter 720a can include two inputs 723a, 725a configured to receive the higher supply voltage and the lower supply voltage for the first inverting circuit 710a, respectively. The second inverter 720a can further include an input 722a coupled to the first output 714a of the first inverting circuit 710a and an output 724a coupled to the operation driver circuit 700b. Similarly, the pre-driver circuit 700a further includes an optional second inverter 720b coupled between the second inverting circuit 710b and the operation driver circuit 700b, and the second inverter 720b can include two inputs 723b, 725b configured to receive the higher supply voltage and the lower supply voltage for the second inverting circuit 710b, respectively. The second inverter 720b can further include an input 722b coupled to the second output 714b of the second inverting circuit 710b and an output 724b coupled to the operation driver circuit 700b. The second inverter 720a, 720b can have a same inverter structure as the inverter 742 of FIG. 7-2, including a pair of a p-type transistor, e.g., a PMOS transistor, and an n-type transistor, e.g., an NMOS transistor. The second inverters 720a, 720b are configured to enable a full voltage swing, e.g., a 0-1.8V swing, using low voltage, e.g., 0.9 V, devices without any device getting over-voltaged.

In some examples, the operation driver circuit 700b includes two inputs 733, 735 as the first input and the second input respectively coupled to the output 724a of the second inverter 720a in the first signal path and the output 724b of the second inverter 720b in the second signal path to respectively receive a first output signal of the first signal path and a second output signal of the second signal path, a third input 732 for receiving a fifth supply voltage, e.g., 0.9 V, identical to the first lower voltage, and an output 734 coupled to the output 703 of the pre-driver circuit 700. The operation driver circuit 700b generates an output signal at the output 734 based on the first output signal of the first signal path received at the input 733 and the second output signal of the second signal path received at the input 735. In some examples, the operation driver circuit 700b includes a third inverter 730, e.g., as illustrated in FIG. 7-1. The third inverter 730 can have an inverter structure same as the inverter 742 of FIG. 7-2. In some examples, the operation driver circuit 610b in the circuit of FIG. 6-1 can be used in place of the operation driver circuit 700b.

The pre-driver circuit 700a can be configured to adjust a rising time of the rising edge of the output signal and/or the falling time of the falling edge of the output signal at the output 703, e.g., using the feedback circuit 750 to control an inversion strength of the first input signal to the first output signal based on a number of pairs of p-type transistor and n-type transistor selected by the first control signal 751 and/or the second control signal 753 in the feedback circuit 750. As described above, the rising edge of an optical signal can be sharper than the falling edge of the optical signal. To compensate the asymmetric edges of the optical signal and make edges of the modulated optical signal be symmetric, the at least one of the first inverting circuit 710a or the second inverting circuit 710b can be configured as described above to cause the falling edge of the output signal at the output 703 to be sharper than the rising edge of the output signal, so as to compensate a difference between the rising edge and the falling edge of the optical signal and a nonlinear response of the optical modulator to the optical signal.

As described above, the feedback circuit 750 can be configured to adjust the inversion strength with multiple levels with an increment of 2^{-N} of a maximum strength per level based on the number of pairs of p-type transistor and n-type transistors selected by the first control signal 751 and/or the second control signal 753, the at least one of the first inverting circuit 710a or the second inverting circuit 710b can adjust the rising time of the rising edge and the falling time of the falling edge of the output signal to change the rising edge and the falling edge of the modulated optical signal. The modulated optical signal can vary between a higher level and a lower level, and the modulated optical signal defines a crosspoint between a corresponding rising edge and a corresponding failing edge of the modulated optical signal. The at least one of the first inverting circuit 710a or the second inverting circuit 710b can be configured to control the crosspoint to move between the higher level and the lower level, e.g., as illustrated in FIG. 7-3, for example, to a middle point to make the rising edge and the falling edge of the modulated output signal symmetric. In this way, the optical modulator can be calibrated to output a modulated optical signal having the rising edge and the falling edge be symmetric. The calibration can be performed before the driver 700 starts to work or is put into service. In some examples, the calibration is performed as part of a build process after an EIC including the driver 700 and a PIC including the optical modulator are paired. In some examples, the driver 700 and the optical modulator are coupled together to perform the calibration, and then the EIC including the driver and the PIC including the optical modulator are coupled together. In some examples, each optical modulator is calibrated on each PIC. In some examples, the calibration is automated as part of a manufacturing process of the optical modulator. After the calibration, information of the first control signal and/or the second control signal 753 used to calibrate the optical modulator are stored and used while the driver 700 is in use with the optical modulator.

FIG. 7-3 is a diagram illustrating an example 770 of operating the driver 700 of FIG. 7-1 to control optical eye diagrams. As described above, the modulated optical signal from the optical modulator can be controlled by controlling the driver 700, e.g., by digitally controlling one or more control signals to a first feedback circuit in the first inverting circuit 710a, e.g., the feedback circuit 750 in the inverting circuit 740, and/or to a second feedback circuit in the second inverting circuit 710b, e.g., the feedback circuit 750 in the inverting circuit 740. For example, as illustrated in FIG. 7-3, by controlling a position of a slider along a sliding bar 772, or affordance, in a graphical user interface (GUI) of a program running on a computing device that is electrically coupled to a register storing values that determine the values of the control signals, e.g., control signals 751, 753, values of the one or more control signals to the first feedback circuit and/or the second feedback circuit can be changed, thereby changing the inversion strength of the first feedback circuit and/or the second feedback circuit.

As described above, accordingly, the modulated optical signal can be controlled such that a crosspoint of the modulated optical signal can be moved up and down between a higher level and a lower level. As an example, as shown in FIG. 7-3, when corresponding curves 774a to 774c of the modulated optical signal changes, corresponding crosspoints 776a to 776e of the corresponding curves 774a to 774e are also changed.

In some examples, the digital values of the digital signal for the first control signal and/or the second control signal are automatically self-adjusted based on a measurement result of the modulated optical signal, e.g., the positions of the crosspoints of the curves. For instance, but a calibration circuit can be included in the EIC that measures the eye and calibrates accordingly. Alternatively, or additionally, this function can be performed by an external device, such as a high speed scope that allows one to observe the eye-monitor on the bench. The self-adjustment can be done by the EIC including the driver, or by a controller coupled to the EIC.

In some implementations, a driver for an optical modulator, e.g., the optical modulator 608 of FIG. 5, includes a pre-driver circuit, e.g., the pre-driver circuit 700a of FIG. 7-1, and an operation driver circuit, e.g., the operation driver circuit 610b of FIG. 6-1. The operation driver circuit is coupled to the pre-driver circuit. For example, the pre-driver circuit can have two outputs, e.g., the outputs 724a, 724b of FIG. 7-1, that can be coupled to two inputs, e.g., the first input 621 of the first operation circuit 620 and the second input 631 of the second operation circuit 630. As described above, the optical modulator can be calibrated by controlling the pre-driver circuit to make an eye diagram symmetric or a corresponding crosspoint in a middle between adjacent signal levels. The operation driver circuit can be configured for high performance operation. The calibration information of the pre-driver circuit can be provided to the operation driver circuit when the operation driver circuit is active.

As described herein in detail, the present disclosure includes a number of practical applications having features described herein that provide benefits and/or solve problems associated with providing a multi-node computing system with sufficient memory, processing, bandwidth, and energy efficiency constraints for effective operation of AI and/or ML models. Some example benefits are described herein with reference to various features and functionalities provided by the computing system as described. It will be appreciated that benefits explicitly described with reference to one or more examples described herein are provided by way of example and are not intended to be an exhaustive list of all possible benefits of the computing system.

For example, the various circuit packages described herein, and connections thereof may enable the construction of complex topologies of compute and memory nodes that can best serve a specific application. In a simple example, a set of photonic channels connect memory circuit packages with memory nodes (e.g., memory resources) to one or more compute circuit packages with compute nodes. The compute circuit packages, and memory circuit packages can be connected and configured in any number of network topologies which may be facilitated through the use of one or more photonic channels include optical fibers. This may provide the benefit of relieving distance constraints between nodes (compute and/or memory) and, for example, the memory circuit packages can physically be placed arbitrarily far from the compute circuit packages (within the optical budget of the photonic channels).

The various network topologies may provide significant speed and energy savings. For example, photonic transport of data is typically more efficient than an equivalent high-bandwidth electrical interconnect in an EIC of the circuit package itself. By implementing one or more photonic channels, the electrical cost of transmitting data may be significantly reduced. Additionally, photonic channels are typically much faster than electrical interconnects, and thus the use of photonic channels permits the grouping and topology configurations of memory and compute circuit packages that best serve the bandwidth and connectivity needs of a given application. Indeed, the architectural split of memory and compute networks allows each to be optimized for the magnitude of data, traffic patterns, and bandwidth of each network applications. A further added benefit is that of being able to control the power density of the system by spacing memory and compute circuit packages to optimize cooling efficiency, as the distances and arrangements are not dictated by electrical interfaces.

The described compute and memory nodes and fabric of communication links including the modulators and electrical interconnects described above provide a distributed data processing environment, which may be referred to as a fabric-based environment, on which programs can be run. A compute node or memory node in such an environment will generally have installed on it a software stack that runs on one or more processors of the node to provide an operating environment, which may be referred to as a layer, on which program software deployed to the node can run.

The compute and memory nodes of a particular environment can be homogeneous, i.e., all the compute nodes are basically the same and all the memory nodes are basically the same, or they can be heterogeneous.

A compute node has one or more processors that can perform data processing operations, e.g., by executing program instructions, by performing operations implemented in hardware or firmware, by routing a data packet through the electrical interface, or otherwise. The processors can include, for example, CPUs, accelerators of various kinds, e.g., GPUs (graphics processing units), TPUs (tensor processing units), DPUs (data processing units), or programmed FPGAs (field-programmable gate arrays) or other special purpose ASICs (application specific integrated circuits), or by a combination of two or more of them.

A compute node generally has or is directly connected electrically to local memory, e.g., HBM, DDR, L1 and L2 caches, registers and the like.

A memory node, while it may have processors to run software and may have other characteristics of a compute node, has as its primary purpose in a fabric-based environment the purpose of providing access to data, specifically, for example, for use by compute processes running on compute nodes, and to enable other nodes to read and write data over photonic channels connecting the memory node to the other nodes. The memory devices a memory node has for storing data can be of one or more types. They are connected through respective memory controllers, message routers, and photonic interfaces through which other nodes read and write data by sending messages to ports implemented on the memory node.

Compute and memory nodes can have memory devices of one or more kinds, including, for example, flash memory, read-only memory, random-access memory (RAM), static RAM, dynamic RAM (DRAM), synchronous DRAM (SDRAM), double data rate (DDR) based DRAM, or high bandwidth memory (HBM) memory, or a combination of two or more of them.

Unidirectional photonic links have a photonic transmitter at one end and a photonic receiver at the other end linked by an optical waveguide, e.g., a semiconductor waveguide or an optical fiber.

Generally, a photonic channel used in a fabric-based environment is a bidirectional photonic channel, which has at least two unidirectional photonic links that transmit in opposite directions, providing, for example, for the transmission of messages in one direction and acknowledgements in the other.

In some implementations, the nodes of a fabric-based environment include routers to route data from one node, directly or through intermediary nodes, to another. Generally, data is transferred in messages over photonic or electrical channels in response to programs executing on the nodes or to operations of memory controllers or similar devices, for example. Such messages can be sent point-to-point, when the two nodes have links directly connect them, or through routers on one or more intermediary nodes that route messages according to addressing data that is part of the messages.

In some implementations, a compute node will have multiple ports, electrical or photonic or both, each directly connected by a link or channel, e.g., bidirectional channel, to a respective other node; and the messages sent by the compute node will be routed to the messages' target nodes by a router on the compute node that directs the messages to the appropriate port on the compute node. When a data message is received over a port, the router on the receiving node will examine the message header to determine the destination node in the fabric, either the node itself or another node, and process the message accordingly.

The addressing of messages through the fabric-based environment can be implemented in a variety of ways. In some implementations, multiple methods are implemented in the same fabric-based environment. In some addressing methods, messages carry the actual address of the message destination, and routers in the fabric implement what in effect are routing tables to transmit messages toward their destination addresses. In some implementations, the routing tables are updated dynamically in response to information about device failures or losses of connections, for example. In other addressing methods, messages are routed by relative addresses, i.e., addresses expressed as directional steps from the current node. Modeling nodes as points on a 2D, 3D, or higher dimensional grid, a target destination can be represented in a message header as a number of steps, which may be positive, negative, or zero, in each of the dimensions. When a message has been transmitted, the receiving node can update the message header of the message to account for the steps taken by the message from the sender in each dimension, with the result that the message header now contains a relative address relative to the receiving node. In other addressing methods, a combination of direct and relative addresses is used.

Memory nodes can be interconnected by photonic links, e.g., in the form of bidirectional photonic channels, to form a memory fabric. The memory fabric can be part of a server and generally includes multiple nodes in one or more packages. A package can include hundreds of nodes extending in multiple dimensions. A fabric made up of multiple packages can have hundreds of thousands of nodes or more, connected by photonic channels in a 2D, 3D, or higher dimensional memory fabric when the nodes have a sufficient number of photonic ports.

Generally, a fabric-based environment is implemented using packages of nodes. A package, sometimes called a System in Package (SiP), includes multiple nodes that are interconnected potentially both at an electrical layer of the package and on an interconnection substrate, e.g., a PIC, and which can be enclosed in a single casing. Each of the nodes in a package can have electrical connections, photonic connections, or both to other nodes within the package. Connections within a package are referred to as intra-chip connections, with the substrate being considered a chip. Connections between nodes in different packages are referred to as inter-chip connections.

In an environment with multiple packages, some, or all of the nodes in one package have inter-chip photonic connections to nodes in one or more other packages. Generally, these inter-chip photonic connections are made by bidirectional photonic channels.

Generally, a program that runs on a fabric-based environment will be made up of program modules, each constructed to run on one of the nodes of the environment. Generally, each module includes instructions to invoke the services of the software stack on which it is running or of the underlying physical devices of the node, to load and store data, locally or remotely, to perform computing and control operations, and to communicate and coordinate with other modules of the program running on the same node or on other nodes on which the program has also been deployed.

Each of the one or more modules that make up a program can be coded separately for a respective particular kind of node. Or a large program can be broken up automatically, e.g., by a compiler, into separately deployable components to run on the nodes of a fabric-based environment. The environment and the resources available in its nodes and the characteristics of its connections, are described by a physical topology, to define, for example, the target for which the compiler is generating executable code.

A program or the modules of a program can generally be programmed using any suitable procedural, interpreted, or declarative language, or combinations of them, from which executable or interpretable code is automatically generated, e.g., by a compiler, to run on some run-time environment, for example, on some node hardware or some software layer or layers installed on the hardware.

A physical topology generally describes the locations of the nodes, any intra-chip connections, and inter-chip connections each node has to other nodes. In some fabric-based environments, nodes are implemented in packages, and the location of a node may also include the package in which it is found. A physical topology may be stored in a topology file that defines an environment for a compiler or for deployment management software.

Program modules and components of the software stack will generally be deployed to nodes through electrical links from a control computer, which may be one of the nodes of the fabric-based environment programmed to perform this function, or which may be a separate control computer. These links can be direct or indirect, and may be provided by an electrical bus, e.g., a PCIe (Peripheral Component Interconnect Express) bus. In some implementations, the photonic links of the fabric-based environment may also be used to deploy modules and components to nodes.

Executable code can be deployed to nodes directly, or, for example, in containers which can be managed by a container management or orchestration system.

A fabric-based environment will generally include one or more nodes that are connected, or can be connected dynamically, to devices external to the fabric. External devices can include devices, for example, to provide human interaction for programs running on the fabric, or to provide data to, or to receive results from, such programs.

The fabric-based environment can be or be part of a general computing environment for executing programs. The computing environment can include or be associated with a compilation environment. The compilation environment takes a program input, e.g., an input machine learning model, and transforms it into machine-readable form by executing a compiler and a code generator. An input machine learning model can be provided in the form of a TensorFlow model, for example.

The application code generated by the compiler and code generator is, in some implementations, provided to a runtime environment running on the nodes of the computing environment. The runtime environment provides services to the running application code on the computing environment. In some implementations, the nodes of the computing environment include firmware that performs hardware-related operations, e.g., monitoring and driving hardware components of the computing environment, used by the runtime environment and the application code.

The application and runtime environment run on the compute nodes and use, if and as requested by the application, the resources of the fabric-based environment, including, for example, the compute nodes, memory nodes, memory devices, links and channels, routers, and ports.

As discussed herein in detail, the present disclosure includes a number of practical applications having features described herein that provide benefits and/or solve problems associated with providing a multi-node computing system with sufficient memory, processing, bandwidth, and energy efficiency constraints for effective operation of AI and/or ML models. Some example benefits are discussed herein in connection with various features and functionalities provided by the computing system as described.

For example, the various circuit packages described herein, and connections thereof may enable the construction of complex topologies of compute and memory nodes that can best serve a specific application. In a simple example, a set of photonic channels connect memory circuit packages with memory nodes (e.g., memory resources) to one or more compute circuit packages with compute nodes. The compute circuit packages, and memory circuit packages can be connected and configured in any number of network topologies which may be facilitated through the use of one or more photonic channels include optical fibers. This may provide the benefit of relieving distance constraints between nodes (compute and/or memory) and, for example, the memory circuit packages can physically be placed arbitrarily far from the compute circuit packages (within the optical budget of the photonic channels).

The various network topologies may provide significant speed and energy savings. For example, photonic transport of data is typically more efficient than an equivalent high-bandwidth electrical interconnect in an EIC of the circuit package itself. By implementing one or more photonic channels, the electrical cost of transmitting data may be significantly reduced. Additionally, photonic channels are typically much faster than electrical interconnects, and thus the use of photonic channels permits the grouping and topology configurations of memory and compute circuit packages that best serve the bandwidth and connectivity needs of a given application. Indeed, the architectural split of memory and compute networks allows each to be optimized for the magnitude of data, traffic patterns, and bandwidth of each network applications. A further added benefit is that of being able to control the power density of the system by spacing memory and compute circuit packages to optimize cooling efficiency, as the distances and arrangements are not dictated by electrical interfaces.

This specification uses the term “configured to” in connection with systems, apparatus, and computer program components. That a system is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed, perform the operations or actions. That special-purpose circuitry is configured to perform particular operations or actions means that the circuitry circuit elements that, when put into operation, perform the operations or actions.

This specification uses the term “configured to” in connection with systems, apparatus, and computer program components. That a system is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed, perform the operations or actions. That special-purpose circuitry is configured to perform particular operations or actions means that the circuitry circuit elements that, when put into operation, perform the operations or actions.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one example” or “an example” of the present disclosure are not intended to be interpreted as excluding the existence of additional examples that also incorporate the recited features. For example, any element described in relation to an example herein may be combinable with any element of any other example described herein. Numbers, percentages, ratios, or other values stated herein are intended to include that value, and also other values that are “about” or “approximately” the stated value, as would be appreciated by one of ordinary skill in the art encompassed by examples of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to examples disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the examples that falls within the meaning and scope of the claims is to be embraced by the claims.

The terms “approximately,” “about,” and “substantially” as used herein represent an amount close to the stated amount that still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The following numbered paragraphs are non-limiting examples of various embodiments of the present disclosure.
A1. A driver for an optical modulator, the driver including: a first circuit having a first input terminal for receiving a first input electronic signal, a first output terminal coupled to a driver terminal, the driver terminal being an output terminal of the driver, and a first switch coupled between the first input terminal and the first output terminal, the first circuit forming a first signal path; and a second circuit having a second input terminal for receiving a second input electronic signal, a second output terminal coupled to the driver terminal, and a second switch coupled between the second input terminal and the second output terminal, the second circuit forming a second signal path, the second input electronic signal being different from the first input electronic signal, wherein the first circuit includes a first control circuit configured to receive a first control signal and generate a first voltage control signal that is adjustable based on the first control signal, and the first switch is coupled to the first control circuit and configured to receive the first voltage control signal and control the first signal path based on the first voltage control signal and the first input electronic signal, wherein the second circuit includes a second control circuit configured to receive a second control signal and generate a second voltage control signal that is adjustable based on the second control signal, and the second switch is coupled to the second control circuit and configured to receive the second voltage control signal and control the second signal path based on the second voltage control signal and the second input electronic signal, and wherein the first circuit and the second circuit are independently controlled by the first control signal and the second control signal to control a rising edge and a falling edge of an output electronic signal at the driver terminal, the output electronic signal being a modulation signal configured to modulate an optical signal passing through an optical modulator.
A2. The driver of paragraph A1, wherein respective values of the first control signal and the second control signal are set to cause a falling edge of the output electronic signal to be sharper than a rising edge of the output electronic signal to compensate a difference between a rising edge and a falling edge of the optical signal when the rising edge of the optical signal is sharper than the falling edge of the optical signal.
A3. The driver of paragraph A1, wherein respective values of the first control signal and the second control signal are set to control the rising edge and the falling edge of the output electronic signal to thereby cause a rising edge and a falling edge of the modulated optical signal to be symmetric.
A4. The driver of paragraph A1, wherein respective values of the first control signal and the second control signal are set to control a crosspoint between a corresponding rising edge and a corresponding failing edge of the modulated optical signal to move between a higher level and a lower level, around which the modulated optical signal varies.
A5. The driver of paragraph A4, wherein the respective values of the first control signal and the second control signal are set to control the crosspoint to move to a middle between the higher level and the lower level.
A6. The driver of paragraph A1, wherein the first circuit includes a first p-type transistor including a gate terminal coupled to the first input terminal for receiving the first input electronic signal, a source terminal coupled to a first supply voltage, and a drain terminal coupled to the first switch, and wherein the second circuit includes a first n-type transistor including a gate terminal coupled to the second input terminal for receiving the second input electronic signal, a source terminal coupled to a second supply voltage, and a drain terminal coupled to the second switch, the first supply voltage being higher than the second supply voltage.
A7. The driver of paragraph A6, wherein the first switch includes a second p-type transistor including a gate terminal coupled to an output terminal of the first control circuit, a source terminal coupled to the drain terminal for the first p-type transistor, and a drain terminal coupled to the driver terminal, and wherein the second switch includes a second n-type transistor including a gate terminal coupled to an output terminal of the second control circuit, a source terminal coupled to the drain terminal for the first n-type transistor, and a drain terminal coupled to the driver terminal.
A8. The driver of paragraph A1, wherein the first output terminal and the second output terminal are respectively connected to a pair of inductors that are coupled with each other, the pair of the inductors being connected to the driver terminal, and wherein the output electronic signal is generated by the pair of inductors coupling a first output electronic signal at the first output terminal and a second output electronic signal at the second output terminal.
A9. The driver of paragraph A8, wherein the pair of inductors include a T-coil having input terminals respectively coupled to the first output terminal and the second output terminal and an output terminal coupled to the driver terminal, and wherein the first switch includes a p-type transistor and the second switch includes an n-type transistor, and the T-coil is coupled between a drain terminal of the p-type transistor and a drain terminal of the n-type transistor.
A10. The driver of paragraph A1, wherein the first control circuit includes a first digital to analog converter (DAC) coupled to the first input terminal of the first switch, and the second control circuit includes a second DAC coupled to the second input terminal of the second switch, wherein the first control signal is a first digital signal and the first DAC is configured to convert the first digital signal into the first voltage control signal that is one of a first series of discrete voltages, and the second control signal is a second digital signal and the second DAC is configured to convert the second digital signal into the second control signal that is one of a second series of discrete voltages.
A11. The driver of paragraph A1, further including: a driver input circuit configured to receive a driver input electronic signal and output the first input electronic signal to the first circuit and the second input electronic signal to the second circuit, wherein the driver input circuit is configured such that the first input electronic signal has a different voltage swing from the second input electronic signal.
A12. The driver of paragraph 11, wherein the driver input circuit includes a pair of a p-type transistor and an n-type transistor, an inductor, and a capacitor, and wherein gate terminals of the p-type transistor and the n-type transistor are configured to receive the driver input electronic signal, drain terminals of the p-type transistor and the n-type transistor are coupled to the second input terminal, the inductor is coupled between the gate terminals and the drain terminals, and the capacitor is coupled between the first input terminal and the second input terminal.
A13. The driver of paragraph A12, wherein the first input electronic signal has a first voltage swing between a first higher voltage and a first lower voltage, and the second input electronic signal has a second voltage swing between a second higher voltage and a second lower voltage, and the first lower voltage is identical to or higher than the second higher voltage.
A14. The driver of paragraph A13, wherein a source terminal of the p-type transistor is coupled to a first supply voltage identical to the first higher voltage, and a source terminal of the n-type transistor is coupled to a second supply voltage identical to the second lower voltage, whereby a range of the second voltage swing is identical to a range of a voltage swing of the driver input electronic signal.
A15. The driver of paragraph A1, wherein the driver is configured such that the modulated optical signal has one of: two non-return-to-zero (NRZ) levels with a throughput of 1 bit per Unit Interval (UI), or four complementary pulse-amplitude-modulation (PAM4) levels with a throughput of 2 bits per Unit Interval (UI).
A16. The driver of paragraph A1, wherein the optical modulator includes an electro-absorption modulator (EAM) based on Franz-Keldysh effect or quantum confined stark effect (QCSE).
A17. The driver of paragraph A1, wherein the driver is arranged in an electric chip (EIC), and the optical modulator is in a photonic chip (PIC), and wherein the driver and the optical modulator are stacked together and coupled through an electronic interconnect between the EIC and the PIC, the driver being positioned adjacent to the electronic interconnect.
A18. An apparatus, including: a photonic integrated circuit (PIC) including an optical modulator; and an electronic integrated circuit (EIC) including a driver, wherein the driver and the optical modulator are stacked together and coupled through an electronic interconnect between the EIC and the PIC, wherein the driver includes: a first circuit having a first input terminal for receiving a first input electronic signal, a first output terminal coupled to a driver terminal, the driver terminal being an output terminal of the driver, and a first switch coupled between the first input terminal and the first output terminal, the first circuit forming a first signal path; and a second circuit having a second input terminal for receiving a second input electronic signal, a second output terminal coupled to the driver terminal, and a second switch coupled between the second input terminal and the second output terminal, the second circuit forming a second signal path, the second input electronic signal being different from the first input electronic signal, wherein the first circuit includes a first control circuit configured to receive a first control signal and generate a first voltage control signal that is adjustable based on the first control signal, and the first switch is coupled to the first control circuit and configured to receive the first voltage control signal and control the first signal path based on the first voltage control signal and the first input electronic signal, wherein the second circuit includes a second control circuit configured to receive a second control signal and generate a second voltage control signal that is adjustable based on the second control signal, and the second switch is coupled to the second control circuit and configured to receive the second voltage control signal and control the second signal path based on the second voltage control signal and the second input electronic signal, and wherein the first circuit and the second circuit are independently controlled by the first control signal and the second control signal to control a rising edge and a falling edge of an output electronic signal at the driver terminal, the output electronic signal being a modulation signal configured to modulate an optical signal passing through an optical modulator.
A19. The apparatus of paragraph A18, wherein respective values of the first control signal and the second control signal are set to control a crosspoint between a corresponding rising edge and a corresponding failing edge of the modulated optical signal to move between a higher level and a lower level, around which the modulated optical signal varies.
A20. The apparatus of paragraph A18, wherein the first circuit includes a first p-type transistor including a gate terminal coupled to the first input terminal for receiving the first input electronic signal, a source terminal coupled to a first supply voltage, and a drain terminal coupled to the first switch, and wherein the second circuit includes a first n-type transistor including a gate terminal coupled to the second input terminal for receiving the second input electronic signal, a source terminal coupled to a second supply voltage, and a drain terminal coupled to the second switch, the first supply voltage being higher than the second supply voltage, and wherein the first switch includes a second p-type transistor including a gate terminal coupled to an output terminal of the first control circuit, a source terminal coupled to the drain terminal for the first p-type transistor, and a drain terminal coupled to the driver terminal, and wherein the second switch includes a second n-type transistor including a gate terminal coupled to an output terminal of the second control circuit, a source terminal coupled to the drain terminal for the first n-type transistor, and a drain terminal coupled to the driver terminal.
A21. The apparatus of paragraph A18, wherein the first output terminal and the second output terminal are respectively connected to a pair of inductors that are coupled with each other, the pair of the inductors being connected to the driver terminal, and wherein the output electronic signal is generated by the pair of inductors coupling a first output electronic signal at the first output terminal and a second output electronic signal at the second output terminal.
A22. The apparatus of paragraph A18, wherein the first control circuit includes a first digital to analog converter (DAC) coupled to the first input terminal of the first switch, and the second control circuit includes a second DAC coupled to the second input terminal of the second switch, wherein the first control signal is a first digital signal and the first DAC is configured to convert the first digital signal into the first voltage control signal that is one of a first series of discrete voltages, and the second control signal is a second digital signal and the second DAC is configured to convert the second digital signal into the second control signal that is one of a second series of discrete voltages.
A23. The apparatus of paragraph A18, wherein the driver further includes a driver input circuit configured to receive a driver input electronic signal and output the first input electronic signal to the first circuit and the second input electronic signal to the second circuit, and wherein the driver input circuit is configured such that the first input electronic signal has a different voltage swing from the second input electronic signal, and wherein the first input electronic signal has a first voltage swing between a first higher voltage and a first lower voltage, and the second input electronic signal has a second voltage swing between a second higher voltage and a second lower voltage, the first lower voltage being identical to or higher than the second higher voltage.
A24. The apparatus of paragraph A18, wherein the driver is configured such that the modulated optical signal has one of: two non-return-to-zero (NRZ) levels with a throughput of 1 bit per Unit Interval (UI), or four complementary pulse-amplitude-modulation (PAM4) levels with a throughput of 2 bits per Unit Interval (UI).
A25. A method for driving an optical modulator, the method including: controlling a first switch coupled between a first input terminal and a first output terminal of a first circuit of a driver by a first control signal, the first output terminal being coupled to a driver terminal of the driver, the driver terminal being an output terminal of the driver that is coupled to the optical modulator; controlling a second switch coupled between a second input terminal and a second output terminal of a second circuit of the driver by a second control signal, the second output terminal being coupled to the driver terminal of the driver; outputting an output electronic signal at the output terminal of the driver to the optical modulator to modulate an optical signal passing through the optical modulator; and adjusting the first control signal and the second control signal to control the output electronic signal to thereby change a shape of the modulated optical signal.
A26. The method of paragraph A25, wherein adjusting the first control signal and the second control signal to control the output electronic signal to thereby change a shape of the modulated optical signal includes: independently adjusting respective values of the first control signal and the second control signal to cause a falling edge of the output electronic signal to be sharper than a rising edge of the output electronic signal to compensate a difference between a rising edge and a falling edge of the optical signal when the rising edge of the optical signal is sharper than the falling edge of the optical signal.
A27. The method of paragraph A26, wherein adjusting the first control signal and the second control signal to control the output electronic signal to thereby change a shape of the modulated optical signal includes: adjusting the first control signal and the second control signal to cause a rising edge and a falling edge of the modulated optical signal to be symmetric, or move a crosspoint between a rising edge and a failing edge of the modulated optical signal to a middle between a higher level and a lower level, around which the modulated optical signal varies.
A28. The method of paragraph A25, wherein: controlling the first switch coupled between the first input terminal and the first output terminal of the first circuit of the driver by the first control signal includes: converting the first control signal into a first voltage control signal by a first digital to analog converter (DAC) coupled to the first input terminal of the first switch, wherein the first control signal is a first digital signal, and the first voltage control signal is one of a first series of discrete voltages, and controlling the second switch coupled between the second input terminal and the second output terminal of the second circuit of the driver by the second control signal includes: converting the second control signal into a second voltage control signal by a second DAC coupled to the second input terminal of the second switch, wherein the second control signal is a second digital signal, and the second voltage control signal is one of a second series of discrete voltages.
A29. The method of paragraph A25, further including: generating the output electronic signal at the driver terminal of the driver by a pair of inductors coupling a first output electronic signal at the first output terminal and a second output electronic signal at the second output terminal.
A30. The method of paragraph A25, further including: generating, based on a driver input electronic signal, a first input electronic signal to be output to the first input terminal of the first circuit and a second input electronic signal to be output to the second input terminal of the second circuit, wherein the first input electronic signal has a first voltage swing between a first higher voltage and a first lower voltage, and the second input electronic signal has a second voltage swing between a second higher voltage and a second lower voltage, the first lower voltage being identical to or higher than the second higher voltage.
B1. A driver for an optical modulator, the driver including: a first inverting circuit having a first input terminal for receiving a first input electronic signal and a first output terminal electrically coupled to a driver terminal of the driver, the driver terminal being an output terminal of the driver; and a second inverting circuit having a second input terminal for receiving a second input electronic signal and a second output terminal electrically coupled to the driver terminal of the driver, the first inverting circuit and the second inverting circuit being configured to control an output electronic signal at the driver terminal of the driver, the output electronic signal being based on a combination of a first output electronical signal at the first output terminal and a second output electronical signal at the second output terminal, the driver terminal of the driver being electrically coupled to the optical modulator to provide the output electronic signal to the optical modulator for modulating an optical signal based on the output electronic signal, and at least one of the first inverting circuit or the second inverting circuit including: an inverter electrically coupled between a corresponding input terminal and a corresponding output terminal; and a feedback circuit electrically coupled the corresponding output back to the corresponding input terminal, the feedback circuit being configured to control an inversion strength from a corresponding input electronical signal to a corresponding output electronical signal to adjust the output electronic signal and the modulated optical signal.
B2. The driver of paragraph B1, wherein the first inverting circuit includes a first feedback circuit configured to receive a first control signal, and the second inverting circuit includes a second feedback circuit configured to receive a second control signal, and wherein the first feedback circuit and the second feedback circuit are independently and respectively controlled by the first control signal and the second control signal to cause a falling edge of the output electronic signal to be sharper than a rising edge of the output electronic signal to compensate a difference between a rising edge and a falling edge of the optical signal and a nonlinear response of the optical modulator to the optical signal when the rising edge of the optical signal is sharper than the falling edge of the optical signal.
B3. The driver of paragraph B2, wherein the first feedback circuit and the second feedback circuit are independently and respectively controlled by the first control signal and the second control signal to control the rising edge and the falling edge of the output electronic signal to cause a rising edge and a falling edge of the modulated optical signal to be symmetric.
B4. The driver of paragraph B2, wherein the first feedback circuit and the second feedback circuit are independently and respectively controlled by the first control signal and the second control signal to control a crosspoint between a rising edge and a failing edge of the modulated optical signal to move to a middle between a higher level and a lower level, around which the modulator optical signal varies.
B5. The driver of paragraph B1, wherein the first inverting circuit and the second inverting circuit have a same circuit structure and are configured to independently control at least one of a rising edge or a falling edge of the output electronic signal.
B6. The driver of paragraph B1, wherein the inverter includes a first p-type transistor and a first n-type transistor, and wherein gate terminals of the first p-type transistor and the first n-type transistor are configured to receive the corresponding input electronic signal, drain terminals of the first p-type transistor and the first n-type transistor are coupled to the corresponding output terminal, and a source terminal of the first p-type transistor is configured to receive a higher supply voltage and a source terminal of the first n-type transistor is configured to receive a lower supply voltage.
B7. The driver of paragraph B6, wherein the feedback circuit includes a first pair of a second p-type transistor and a second n-type transistor, wherein gate terminals of the first pair of the second p-type transistor and the second n-type transistor are coupled to the corresponding output terminal, drain terminals of the first pair of the second p-type transistor and the second n-type transistor are coupled to the corresponding input terminal, and wherein a source terminal of the second p-type transistor is configured to receive the higher supply voltage, and a source terminal of the second n-type transistor is configured to receive the lower supply voltage.
B8. The driver of paragraph B7, wherein the feedback circuit further includes one or more additional pairs of a second p-type transistor and a second n-type transistor, wherein the one or more second p-type transistors of the one or more additional pairs are coupled in series between the drain terminal of the second p-type transistor of the first pair and the corresponding input terminal, and the one or more second n-type transistors of the one or more additional pairs are coupled in series between the drain terminal of the second n-type transistor of the first pair and the corresponding input terminal, and wherein a gate terminal of at least one of the one or more second p-type transistors or the one or more second n-type transistors is configured to receive a control signal to adjust the inversion strength.
B9. The driver of paragraph B8, wherein the feedback circuit includes a number of pairs including the first pair and the one or more additional pairs, and the number is 2^{N}, where N is a positive integer, and wherein the feedback circuit is configured to adjust the inversion strength with multiple levels with an increment of 2^{-N} of a maximum strength per level.
B10. The driver of paragraph B8, further including a digital to analog converter (DAC) configured to convert a digital signal into the control signal, such that the modulated optical signal is adjusted based on the digital signal.
B11. The driver of paragraph B6, further including a second inverter coupled between the corresponding output terminal and the driver terminal of the driver, the second inverter having two input terminals configured to receive the higher supply voltage and the lower supply voltage, respectively.
B12. The driver of paragraph B6, wherein the at least one of the first inverting circuit or the second inverting circuit further includes one or more transistors coupled in series between the corresponding input terminal and the corresponding output terminal, and wherein a gate terminal of each of the one or more transistors is configured to receive a gate control signal.
B13. The driver of paragraph B1, further including a driver input circuit coupled between an input terminal of the driver and the first inverting circuit and the second inverting circuit, wherein the driver input circuit is configured to receive a driver input electronic signal at the input terminal of the driver, generate the first input electronic signal and the second input electronic signal that are different from each other, and output the first input electronic signal to the first inverting circuit and the second input electronic signal to the second inverting circuit.
B14. The driver of paragraph B13, wherein the first input signal includes a first voltage swing between a first higher voltage and a first lower voltage, and the second input signal includes a second voltage swing between a second higher voltage and a second lower voltage, and wherein the first lower voltage is identical to or higher than the second higher voltage.
B15. The driver of paragraph B14, wherein the driver input circuit includes a first capacitor coupled between the input terminal of the driver and the first input terminal of the first inverting circuit and a second capacitor coupled between the input terminal of the driver and the second inverting circuit, wherein the driver input circuit is configured such that the second voltage swing is identical to a voltage swing of the input electronic signal and the first lower voltage is identical to the second higher voltage, and wherein the first inverting circuit is configured to receive a first supply voltage identical to the first higher voltage and a second supply voltage identical to the first lower voltage, and the second inverting circuit is configured to receive a third supply voltage identical to the second higher voltage and a fourth supply voltage identical to the second lower voltage.
B16. The driver of paragraph B15, further including another inverter having two input terminals respectively coupled to the first output terminal and the second output terminal, a third input terminal for receiving a fifth supply voltage identical to the first lower voltage, and an output terminal coupled to the driver terminal of the driver.
B17. The driver of paragraph B1, wherein the driver is configured such that the modulated optical signal has one of: two non return to zero (NRZ) levels with a throughput of 1 bit per Unit Interval (UI), or four complementary pulse-amplitude-modulation (PAM4) levels with a throughput of 2 bits per Unit Interval (UI).
B18. The driver of paragraph B1, wherein the optical modulator includes an electro-absorption modulator (EAM) based on Franz-Keldysh effect or quantum confined stark effect (QCSE).
B19. The driver of paragraph B1, wherein the driver is arranged in an electric chip (EIC), and the optical modulator is in a photonic chip (PIC), and wherein the driver and the optical modulator are stacked together and coupled through an electronic interconnect between the EIC and the PIC, the driver being positioned adjacent to the electronic interconnect.
B20. An apparatus, including: a photonic integrated circuit (PIC) including an optical modulator; and an electronic integrated circuit (EIC) including a driver, wherein the driver and the optical modulator are stacked together and coupled through an electronic interconnect between the EIC and the PIC, wherein the driver includes: a first inverting circuit having a first input terminal for receiving a first input electronic signal and a first output electrically coupled to a driver terminal of the driver, wherein the driver terminal is an output terminal of the driver; and a second inverting circuit having a second input terminal for receiving a second input electronic signal and a second output electrically coupled to the driver terminal of the driver, the first inverting circuit and the second inverting circuit being configured to control an output electronic signal at the driver terminal of the driver, the output electronic signal being based on a combination of a first output electronic signal at the first output terminal and a second output electronic signal at the second output terminal, the driver terminal of the driver being electrically coupled to the optical modulator to provide the output electronic signal to the optical modulator for modulating an optical signal based on the output electronic signal, and at least one of the first inverting circuit or the second inverting circuit including: an inverter electrically coupled between a corresponding input terminal and a corresponding output terminal; and a feedback circuit electrically coupled the corresponding output terminal back to the corresponding input terminal, the feedback circuit being configured to control an inversion strength from a corresponding input electronic signal to a corresponding output electronic signal to adjust the output electronic signal and the modulated optical signal.
B21. The apparatus of paragraph B20, wherein the driver includes a pre-driver circuit configured to calibrate the optical modulator, the pre-driver circuit including the first inverting circuit and the second inverting circuit, and wherein the driver further includes an operation driver circuit configured to drive the optical modulator based on calibration information of the pre-driver circuit.
B22. The apparatus of paragraph B21, wherein the operation driver circuit includes: a first operation circuit having a first operation input terminal for receiving a first operation input signal, a first operation output terminal electrically coupled to an output terminal of the operation driver circuit, and a first switch electrically coupled between the first operation input terminal and the first operation output terminal, the first operation circuit forming a first signal path; and a second operation circuit having a second operation input terminal for receiving a second operation input signal, a second output terminal electrically coupled to the output terminal of the operation driver circuit, and a second switch electrically coupled between the second operation input terminal and the second operation output terminal, the second operation circuit forming a second signal path, the second operation input signal being different from the first operation input signal, the first switch being configured to receive a first control signal that is changeable to control the first signal path based on the first operation input signal, and wherein the second switch is configured to receive a second control signal that is changeable to control the second signal path based on the second operation input signal, the first operation circuit and the second operation circuit being configured to control a rising edge and a falling edge of an operation output electronic signal at the output terminal of the operation driver circuit, the operation output electronic signal being based on a combination of a first operation output signal at the first operation output terminal and a second output signal at the second output terminal, and the output terminal of the operation driver circuit being electrically coupled to the optical modulator to provide the operation output electronic signal to the optical modulator.
B23. A driver for an optical modulator, the driver including: a pre-driver circuit configured to calibrate the optical modulator; and an operation driver circuit configured to drive the optical modulator based on calibration information of the pre-driver circuit, wherein the pre-driver circuit includes: a first inverting circuit having a first input terminal for receiving a first input electronic signal and a first output terminal electrically coupled to an output terminal of the pre-driver circuit; and a second inverting circuit having a second input terminal for receiving a second input electronic signal and a second output terminal electrically coupled to the output terminal of the pre-driver circuit, the second input electronic signal being different from the first input electronic signal, the first inverting circuit and the second inverting circuit being configured to control an output electronic signal at the output terminal of the pre-driver circuit, the output electronic signal being based on a combination of a first output electronic signal at the first output terminal and a second output electronic signal at the second output terminal, the output terminal of the pre-driver circuit being electrically coupled to the optical modulator to provide the output electronic signal to the optical modulator for modulating an optical signal based on the output electronic signal, and at least one of the first inverting circuit or the second inverting circuit including: an inverter electrically coupled between a corresponding input terminal and a corresponding output terminal; and a feedback circuit electrically coupled the corresponding output terminal back to the corresponding input terminal, wherein the feedback circuit is configured to control an inversion strength from a corresponding input electronic signal to a corresponding output electronic signal to adjust the output electronic signal and the modulated optical signal, and wherein the operation driver circuit includes: a first operation circuit having a first operation input terminal for receiving a first operation input signal, a first operation output terminal electrically coupled to an output terminal of the operation driver circuit, and a first switch electrically coupled between the first operation input terminal and the first operation output terminal, the first operation circuit b forming a first signal path; and a second operation circuit having a second operation input terminal for receiving a second operation input signal, a second output terminal electrically coupled to the output terminal of the operation driver circuit, and a second switch electrically coupled between the second operation input terminal and the second operation output terminal, the second operation circuit forming a second signal path, the second operation input signal being different from the first operation input signal, the first switch being configured to receive a first control signal that is changeable to control the first signal path based on the first operation input signal, and wherein the second switch is configured to receive a second control signal that is changeable to control the second signal path based on the second operation input signal, the first operation circuit and the second operation circuit being configured to control a rising edge and a falling edge of an operation output electronic signal at the output terminal of the operation driver circuit, the operation output electronic signal being based on a combination of a first operation output signal at the first operation output terminal and a second output signal at the second output terminal, and the driver terminal of the operation driver circuit being electrically coupled to the optical modulator to provide the operation output electronic signal to the optical modulator.

Particular implementations of the subject matter have been described. Other implementations are within the scope of the following claims.

What is claimed is:

1. A driver for an optical modulator, the driver comprising:
a first inverting circuit having a first input terminal for receiving a first input electronic signal and a first output terminal electrically coupled to a driver terminal of the driver, the driver terminal being an output terminal of the driver; and
a second inverting circuit having a second input terminal for receiving a second input electronic signal and a second output terminal electrically coupled to the driver terminal of the driver,
the first inverting circuit and the second inverting circuit being configured to control an output electronic signal at the driver terminal of the driver, the output electronic signal being based on a combination of a first output electronical signal at the first output terminal and a second output electronical signal at the second output terminal,
the driver terminal of the driver being electrically coupled to the optical modulator to provide the output electronic signal to the optical modulator for modulating an optical signal based on the output electronic signal, and
at least one of the first inverting circuit or the second inverting circuit comprising:
an inverter electrically coupled between a corresponding input terminal and a corresponding output terminal; and
a feedback circuit electrically coupled the corresponding output back to the corresponding input terminal,
the feedback circuit being configured to control an inversion strength from a corresponding input electronical signal to a corresponding output electronical signal to adjust the output electronic signal and the modulated optical signal.

2. The driver of claim 1, wherein the first inverting circuit comprises a first feedback circuit configured to receive a first control signal, and the second inverting circuit comprises a second feedback circuit configured to receive a second control signal, and
wherein the first feedback circuit and the second feedback circuit are independently and respectively controlled by the first control signal and the second control signal to cause a falling edge of the output electronic signal to be sharper than a rising edge of the output electronic signal to compensate a difference between a rising edge and a falling edge of the optical signal and a nonlinear response of the optical modulator to the optical signal when the rising edge of the optical signal is sharper than the falling edge of the optical signal.

3. The driver of claim 2, wherein the first feedback circuit and the second feedback circuit are independently and respectively controlled by the first control signal and the second control signal to control the rising edge and the falling edge of the output electronic signal to cause a rising edge and a falling edge of the modulated optical signal to be symmetric.

4. The driver of claim 2, wherein the first feedback circuit and the second feedback circuit are independently and respectively controlled by the first control signal and the second control signal to control a crosspoint between a rising edge and a failing edge of the modulated optical signal to move to a middle between a higher level and a lower level, around which the modulator optical signal varies.

5. The driver of claim 1, wherein the first inverting circuit and the second inverting circuit have a same circuit structure and are configured to independently control at least one of a rising edge or a falling edge of the output electronic signal.

6. The driver of claim 1, wherein the inverter comprises a first p-type transistor and a first n-type transistor, and
wherein gate terminals of the first p-type transistor and the first n-type transistor are configured to receive the corresponding input electronic signal, drain terminals of the first p-type transistor and the first n-type transistor are coupled to the corresponding output terminal, and a source terminal of the first p-type transistor is configured to receive a higher supply voltage and a source terminal of the first n-type transistor is configured to receive a lower supply voltage.

7. The driver of claim 6, wherein the feedback circuit comprises a first pair of a second p-type transistor and a second n-type transistor,
wherein gate terminals of the first pair of the second p-type transistor and the second n-type transistor are coupled to the corresponding output terminal, drain terminals of the first pair of the second p-type transistor and the second n-type transistor are coupled to the corresponding input terminal, and
wherein a source terminal of the second p-type transistor is configured to receive the higher supply voltage, and a source terminal of the second n-type transistor is configured to receive the lower supply voltage.

8. The driver of claim 7, wherein the feedback circuit further comprises one or more additional pairs of a second p-type transistor and a second n-type transistor,
wherein the one or more second p-type transistors of the one or more additional pairs are coupled in series between the drain terminal of the second p-type transistor of the first pair and the corresponding input terminal, and the one or more second n-type transistors of the one or more additional pairs are coupled in series between the drain terminal of the second n-type transistor of the first pair and the corresponding input terminal, and
wherein a gate terminal of at least one of the one or more second p-type transistors or the one or more second n-type transistors is configured to receive a control signal to adjust the inversion strength.

9. The driver of claim 8, wherein the feedback circuit comprises a number of pairs including the first pair and the one or more additional pairs, and the number is 2^{N}, where N is a positive integer, and
wherein the feedback circuit is configured to adjust the inversion strength with multiple levels with an increment of 2^{-N} of a maximum strength per level.

10. The driver of claim 8, further comprising a digital to analog converter (DAC) configured to convert a digital signal into the control signal, such that the modulated optical signal is adjusted based on the digital signal.

11. The driver of claim 6, further comprising a second inverter coupled between the corresponding output terminal and the driver terminal of the driver, the second inverter having two input terminals configured to receive the higher supply voltage and the lower supply voltage, respectively.

12. The driver of claim 6, wherein the at least one of the first inverting circuit or the second inverting circuit further comprises one or more transistors coupled in series between the corresponding input terminal and the corresponding output terminal, and wherein a gate terminal of each of the one or more transistors is configured to receive a gate control signal.

13. The driver of claim 1, further comprising a driver input circuit coupled between an input terminal of the driver and the first inverting circuit and the second inverting circuit,
wherein the driver input circuit is configured to receive a driver input electronic signal at the input terminal of the driver, generate the first input electronic signal and the second input electronic signal that are different from each other, and output the first input electronic signal to the first inverting circuit and the second input electronic signal to the second inverting circuit.

14. The driver of claim 13, wherein the first input signal comprises a first voltage swing between a first higher voltage and a first lower voltage, and the second input signal comprises a second voltage swing between a second higher voltage and a second lower voltage, and
wherein the first lower voltage is identical to or higher than the second higher voltage.

15. The driver of claim 14, wherein the driver input circuit comprises a first capacitor coupled between the input terminal of the driver and the first input terminal of the first inverting circuit and a second capacitor coupled between the input terminal of the driver and the second inverting circuit,
wherein the driver input circuit is configured such that the second voltage swing is identical to a voltage swing of the input electronic signal and the first lower voltage is identical to the second higher voltage, and
wherein the first inverting circuit is configured to receive a first supply voltage identical to the first higher voltage and a second supply voltage identical to the first lower voltage, and the second inverting circuit is configured to receive a third supply voltage identical to the second higher voltage and a fourth supply voltage identical to the second lower voltage.

16. The driver of claim 15, further comprising another inverter having two input terminals respectively coupled to the first output terminal and the second output terminal, a third input terminal for receiving a fifth supply voltage identical to the first lower voltage, and an output terminal coupled to the driver terminal of the driver.

17. The driver of claim 1, wherein the driver is configured such that the modulated optical signal has one of:
two non return to zero (NRZ) levels with a throughput of 1 bit per Unit Interval (UI), or
four complementary pulse-amplitude-modulation (PAM4) levels with a throughput of 2 bits per Unit Interval (UI).

18. The driver of claim 1, wherein the optical modulator comprises an electro-absorption modulator (EAM) based on Franz-Keldysh effect or quantum confined stark effect (QCSE).

19. The driver of claim 1, wherein the driver is arranged in an electric chip (EIC), and the optical modulator is in a photonic chip (PIC), and wherein the driver and the optical modulator are stacked together and coupled through an electronic interconnect between the EIC and the PIC, the driver being positioned adjacent to the electronic interconnect.

20. An apparatus, comprising:
a photonic integrated circuit (PIC) comprising an optical modulator; and
an electronic integrated circuit (EIC) comprising a driver, wherein the driver and the optical modulator are stacked together and coupled through an electronic interconnect between the EIC and the PIC,
wherein the driver comprises:
a first inverting circuit having a first input terminal for receiving a first input electronic signal and a first output electrically coupled to a driver terminal of the driver, wherein the driver terminal is an output terminal of the driver; and
a second inverting circuit having a second input terminal for receiving a second input electronic signal and a second output electrically coupled to the driver terminal of the driver,
the first inverting circuit and the second inverting circuit being configured to control an output electronic signal at the driver terminal of the driver, the output electronic signal being based on a combination of a first output electronic signal at the first output terminal and a second output electronic signal at the second output terminal,
the driver terminal of the driver being electrically coupled to the optical modulator to provide the output electronic signal to the optical modulator for modulating an optical signal based on the output electronic signal, and
at least one of the first inverting circuit or the second inverting circuit comprising: an inverter electrically coupled between a corresponding input terminal and a corresponding output terminal; and a feedback circuit electrically coupled the corresponding output terminal back to the corresponding input terminal, the feedback circuit being configured to control an inversion strength from a corresponding input electronic signal to a corresponding output electronic signal to adjust the output electronic signal and the modulated optical signal.

21. The apparatus of claim 20, wherein the driver comprises a pre-driver circuit configured to calibrate the optical modulator, the pre-driver circuit comprising the first inverting circuit and the second inverting circuit, and
wherein the driver further comprises an operation driver circuit configured to drive the optical modulator based on calibration information of the pre-driver circuit.

22. The apparatus of claim 21, wherein the operation driver circuit comprises:
a first operation circuit having a first operation input terminal for receiving a first operation input signal, a first operation output terminal electrically coupled to an output terminal of the operation driver circuit, and a first switch electrically coupled between the first operation input terminal and the first operation output terminal, the first operation circuit forming a first signal path; and
a second operation circuit having a second operation input terminal for receiving a second operation input signal, a second output terminal electrically coupled to the output terminal of the operation driver circuit, and a second switch electrically coupled between the second operation input terminal and the second operation output terminal, the second operation circuit forming a second signal path, the second operation input signal being different from the first operation input signal,
the first switch being configured to receive a first control signal that is changeable to control the first signal path based on the first operation input signal, and wherein the second switch is configured to receive a second control signal that is changeable to control the second signal path based on the second operation input signal,
the first operation circuit and the second operation circuit being configured to control a rising edge and a falling edge of an operation output electronic signal at the output terminal of the operation driver circuit, the operation output electronic signal being based on a combination of a first operation output signal at the first operation output terminal and a second output signal at the second output terminal, and
the output terminal of the operation driver circuit being electrically coupled to the optical modulator to provide the operation output electronic signal to the optical modulator.

23. A driver for an optical modulator, the driver comprising:
a pre-driver circuit configured to calibrate the optical modulator; and
an operation driver circuit configured to drive the optical modulator based on calibration information of the pre-driver circuit,
wherein the pre-driver circuit comprises:
a first inverting circuit having a first input terminal for receiving a first input electronic signal and a first output terminal electrically coupled to an output terminal of the pre-driver circuit; and
a second inverting circuit having a second input terminal for receiving a second input electronic signal and a second output terminal electrically coupled to the output terminal of the pre-driver circuit, the second input electronic signal being different from the first input electronic signal,
the first inverting circuit and the second inverting circuit being configured to control an output electronic signal at the output terminal of the pre-driver circuit, the output electronic signal being based on a combination of a first output electronic signal at the first output terminal and a second output electronic signal at the second output terminal,
the output terminal of the pre-driver circuit being electrically coupled to the optical modulator to provide the output electronic signal to the optical modulator for modulating an optical signal based on the output electronic signal, and
at least one of the first inverting circuit or the second inverting circuit comprising: an inverter electrically coupled between a corresponding input terminal and a corresponding output terminal; and a feedback circuit electrically coupled the corresponding output terminal back to the corresponding input terminal, wherein the feedback circuit is configured to control an inversion strength from a corresponding input electronic signal to a corresponding output electronic signal to adjust the output electronic signal and the modulated optical signal, and
wherein the operation driver circuit comprises:
a first operation circuit having a first operation input terminal for receiving a first operation input signal, a first operation output terminal electrically coupled to an output terminal of the operation driver circuit, and a first switch electrically coupled between the first operation input terminal and the first operation output terminal, the first operation circuit b forming a first signal path; and
a second operation circuit having a second operation input terminal for receiving a second operation input signal, a second output terminal electrically coupled to the output terminal of the operation driver circuit, and a second switch electrically coupled between the second operation input terminal and the second operation output terminal, the second operation circuit forming a second signal path, the second operation input signal being different from the first operation input signal,
the first switch being configured to receive a first control signal that is changeable to control the first signal path based on the first operation input signal, and wherein the second switch is configured to receive a second control signal that is changeable to control the second signal path based on the second operation input signal,
the first operation circuit and the second operation circuit being configured to control a rising edge and a falling edge of an operation output electronic signal at the output terminal of the operation driver circuit, the operation output electronic signal being based on a combination of a first operation output signal at the first operation output terminal and a second output signal at the second output terminal, and
the driver terminal of the operation driver circuit being electrically coupled to the optical modulator to provide the operation output electronic signal to the optical modulator.
